(19) United States
(12) Patent Application Publication
(10) Pub. No.: US 2022/0382396 A1
(43) Pub. Date: Dec. 1, 2022

(54) SENSOR FILM, TOUCH SENSOR, AND IMAGE DISPLAY DEVICE

(71) Applicant: FUJIFILM Corporation, Tokyo (JP)

(72) Inventors: Kentaro TOYOOKA, Fujinomiya-shi (JP); Masaya Suzuki, Fujinomiya-shi (JP)

(73) Assignee: FUJIFILM Corporation, Tokyo (JP)

(21) Appl. No.: 17/869,349

(22) Filed: Jul. 20, 2022

Related U.S. Application Data
(63) Continuation of application No. PCT/JP2021/001342, filed on Jan. 15, 2021.

(30) Foreign Application Priority Data
Jan. 29, 2020 (JP) 2020-012156

(51) Int. Cl. G06F 3/044; G03F 7/033; G06F 3/041

(52) U.S. Cl. CPC G06F 3/044; G03F 7/033; G06F 3/04164; G06F 2203/04103

(57) ABSTRACT

A sensor film includes a substrate, a sensor electrode which is disposed on the substrate, a lead wire which is disposed on the substrate, conducts with the sensor electrode, and has a connection terminal, a first protective layer which is disposed on the connection terminal, and a second protective layer which is disposed on at least the sensor electrode or a portion of the lead wire other than the connection terminal, in which the first protective layer satisfies a relationship represented by the following expression (1),

0 V<D×B≤30.0 V (1)
D: Thickness (μm) of the first protective layer
B: Dielectric breakdown voltage (V/μm) of the first protective layer.

### CROSS-REFERENCE TO RELATED APPLICATIONS

This application is a Continuation of PCT International Application No. PCT/JP2021/001342 filed on Jan. 15, 2021, which claims priority under 35 U.S.C § 119(a) to Japanese Patent Application No. 2020-012156 filed on Jan. 29, 2020. Each of the above application(s) is hereby expressly incorporated by reference, in its entirety, into the present application.

### BACKGROUND OF THE INVENTION

### 1. Field of the Invention

The present invention relates to a sensor film, a touch sensor, and an image display device.

### 2. Description of the Related Art

A sensor film such as a touch panel has been used as a display device including large electronic apparatuses such as a personal computer and a television, small electronic apparatuses such as a car navigation system, a mobile phone, and an electronic dictionary, office automation (OA) apparatuses, factory automation (FA) apparatuses, and the like.

As the touch panel, various types have already been put into practical use, and in recent years, the use of a capacitance type touch panel has been increasing.

For example, WO2013/084873A discloses a method for forming a protective film of an electrode for a touch panel, in which a photosensitive layer satisfying a specific requirement is provided on a substrate having an electrode for a touch panel, a predetermined portion of the photosensitive layer is cured and then a portion other than the predetermined portion is removed, and a protective film formed of a cured substance of the predetermined portion of the photosensitive layer covering a part or all of the electrode is formed.

### SUMMARY OF THE INVENTION

The sensor film is required to have good electrical connectivity, and from the viewpoint of durability, is also required to have excellent corrosion resistance.

In a case where the present inventors have studied the method disclosed in JP2013/084873A, the present inventors have found that it is difficult to achieve both excellent electrical connectivity and corrosion resistance.

An object of the present invention is to provide a sensor film having excellent electrical connectivity and corrosion resistance. Another object of the present invention is to provide a touch sensor related to the sensor film and an image display device.

As a result of intensive studies on the above-described objects, the present inventors have found that the above-described objects can be accomplished by the following configurations.

[1]

A sensor film comprising:

a substrate;

a sensor electrode which is disposed on the substrate;

a lead wire which is disposed on the substrate, conducts with the sensor electrode, and has a connection terminal;

a first protective layer which is disposed on the connection terminal; and

a second protective layer which is disposed on at least the sensor electrode or a portion of the lead wire other than the connection terminal,

in which the first protective layer satisfies a relationship represented by the following expression (1),

0 V<D×B≤30.0 V (1)

D: Thickness (μm) of the first protective layer

B: Dielectric breakdown voltage (V/μm) of the first protective layer.

[2]

The sensor film according to [1],

in which the lead wire includes one or more metals selected from the group consisting of copper and silver.

[3]

The sensor film according to [1] or [2],

in which the D is 0.001 μm or more.

[4]

The sensor film according to any one of [1] to [3],

in which the B is 400 V/μm or less.

[5]

The sensor film according to any one of [1] to [4],

in which the first protective layer satisfies a relationship represented by the following expression (3),

10.0 V<D×B≤20.0 V. (3)

[6]

The sensor film according to any one of [1] to [5],

in which the first protective layer includes an azole compound.

[7]

The sensor film according to [6],

in which the azole compound is one or more compounds selected from the group consisting of triazoles, tetrazoles, imidazoles, and thiadiazoles.

[8]

The sensor film according to any one of [1] to [7],

in which the first protective layer includes a binder polymer having a constitutional unit derived from (meth)acrylic acid.

[9]

The sensor film according to any one of [1] to [7],

in which the first protective layer includes a compound having a tricyclodecane skeleton.

[10]

A touch sensor comprising:

the sensor film according to any one of [1] to [9]; and a flexible wiring board connected to the connection terminal.

[11]

An image display device comprising:

the touch sensor according to [10].

According to the present invention, it is possible to provide a sensor film having excellent electrical connectivity and corrosion resistance. In addition, it is possible to provide a touch sensor related to the sensor film and an image display device.

### BRIEF DESCRIPTION OF THE DRAWINGS

FIG. 1 is a schematic top view showing an embodiment of a sensor film of the present invention.

FIG. 2 is a partial cross-sectional view taken along a line V-V shown in FIG. 1.

FIG. 3 is a schematic view showing an example of a configuration of a transfer film.

### DESCRIPTION OF THE PREFERRED EMBODIMENTS

Hereinafter, the present invention will be described in detail.

In the present specification, a numerical value range expressed using “to” means a range that includes the preceding and succeeding numerical values of “to” as a lower limit value and an upper limit value, respectively.

In addition, in a numerical range described in a stepwise manner in the present specification, an upper limit value or a lower limit value described in a certain numerical range may be replaced with an upper limit value or a lower limit value in another numerical range described in a stepwise manner. In addition, regarding the numerical range described in the present specification, an upper limit value or a lower limit value described in a numerical value may be replaced with a value described in Examples.

In addition, a term “step” in the present specification includes not only an independent step but also a step that cannot be clearly distinguished from other steps, as long as the intended purpose of the step is achieved.

In the present specification, “transparent” means that an average transmittance of visible light having a wavelength of 400 nm to 700 nm is 80% or more, preferably 90% or more. Therefore, for example, a “transparent resin layer” refers to a resin layer having an average transmittance of visible light having a wavelength of 400 to 700 nm is 80% or more. In addition, the average transmittance of visible light is a value measured by using a spectrophotometer, and for example, can be measured by using a spectrophotometer U-3310 manufactured by Hitachi, Ltd.

In the present specification, a content ratio of each structural unit of a polymer is a molar ratio unless otherwise specified.

In addition, in the present specification, a refractive index is a value measured with an ellipsometer at a wavelength of 550 nm unless otherwise specified.

In the present specification, unless otherwise specified, a molecular weight in a case of a molecular weight distribution is a weight-average molecular weight. In the present specification, a weight-average molecular weight of a resin is a weight-average molecular weight obtained by performing polystyrene conversion of a value measured by gel permeation chromatography (GPC).

In the present specification, “(meth)acrylic acid” is a concept including both acrylic acid and methacrylic acid, and “(meth)acryloyl group” is a concept including both an acryloyl group and a methacryloyl group.

In the present specification, unless otherwise specified, a thickness of a layer (film thickness) is an average thickness measured using a scanning electron microscope (SEM) for a thickness of 0.5 μm or more, and is an average thickness measured using a transmission electron microscope (TEM) for a thickness of less than 0.5 μm. The average thickness is an average thickness obtained by forming a section to be measured using an ultramicrotome, measuring thicknesses of any five points, and arithmetically averaging the values.

[Sensor Film]

A sensor film according to an embodiment of the present invention is a sensor film which includes a substrate, a sensor electrode which is disposed on the substrate, a lead wire which is disposed on the substrate, conducts with the sensor electrode, and has a connection terminal, a first protective layer which is disposed on the connection terminal, and a second protective layer which is disposed on at least the sensor electrode or a portion of the lead wire other than the connection terminal, in which the first protective layer satisfies a relationship represented by the following expression (1).

0 V<D×B≤30.0 V (1)

D: Thickness (μm) of the first protective layer

B: Dielectric breakdown voltage (V/μm) of the first protective layer

The present inventors have found that, by adopting the configuration of having the above-described first protective layer, good corrosion resistance including a connection terminal portion in a lead wire can be realized without impairing electrical connectivity of the sensor film.

Hereinafter, an embodiment of the sensor film of the present invention will be described with reference to the drawings.

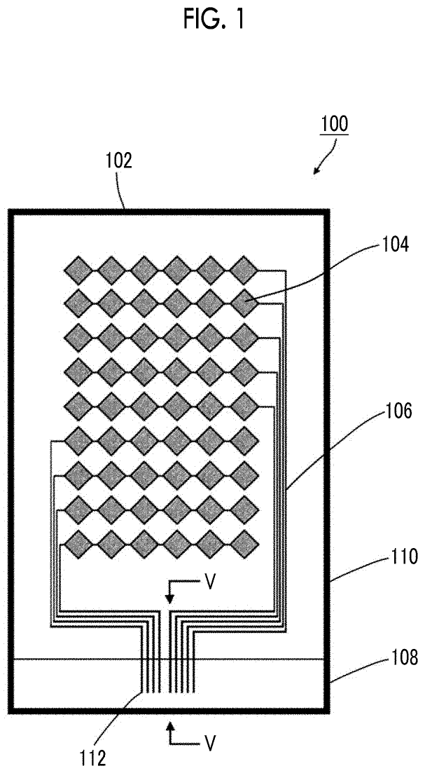

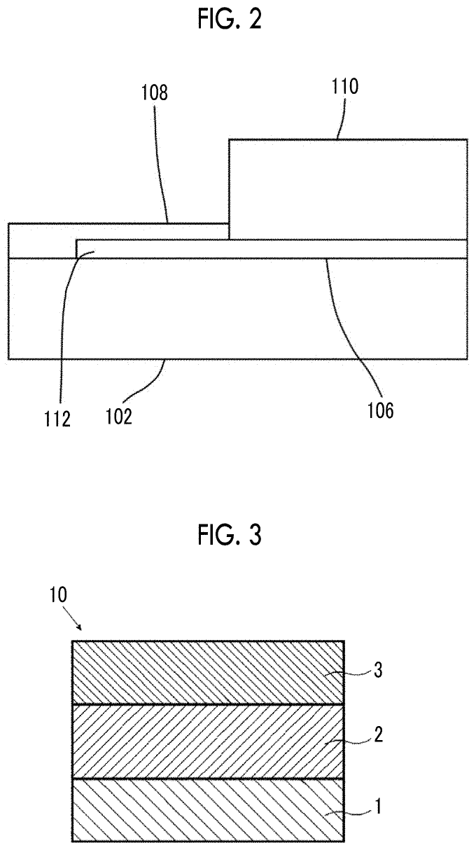

FIG. 1 shows a schematic top view of the sensor film according to the embodiment of the present invention. FIG. 2 is a sectional view taken along a line V-V in FIG. 1.

A sensor film 100 includes a substrate 102, a sensor electrode 104 disposed on the substrate 102, a lead wire 106 which conducts with the sensor electrode 104 and has a connection terminal 112 at one terminal, a first protective layer 108 disposed so as to cover the connection terminal 112, and a second protective layer 110 disposed so as to cover the lead wire 106 not covered by the sensor electrode 104 and the first protective layer 108.

By connecting a flexible wiring board to the connection terminal 112 of the sensor film 100 as described later, the sensor film can be used as a touch panel sensor.

In FIGS. 1 and 2, the terminal of the lead wire 106 opposite to the sensor electrode 104 is the connection terminal 112, but the present invention is not limited to this embodiment, and any position of the lead wire may be the connection terminal.

In FIGS. 1 and 2, the first protective layer 108 is disposed so as to cover a part of the substrate 102 and cover the connection terminal 112 located at one terminal of the lead wire 106, but the present invention is not limited to this embodiment, and it is sufficient that the first protective layer 108 is disposed on the connection terminal 112, and the first protective layer 108 disposed only on the connection terminal 112.

In FIGS. 1 and 2, the second protective layer 110 is disposed so as to cover a part of the substrate 102, cover the sensor electrode 104, and cover a part of the lead wire 106, but the present invention is not limited to this embodiment, and it is sufficient that the second protective layer 110 is disposed on the sensor electrode 104 and on at least a part of the lead wire 106.

Hereinafter, each member will be described in detail.

<Substrate>

The sensor film according to the embodiment of the present invention includes a substrate. The substrate is a member which supports the sensor electrode and the lead wire.

As the substrate, an insulating substrate is preferable.

The substrate is not particularly limited, and examples thereof include a glass substrate and a plastic substrate of polycarbonate, polyethylene terephthalate, polyvinyl chloride, cycloolefin polymer, and the like.

In addition, the substrate may be in a form of a film. Examples of the film-like substrate include a polyethylene terephthalate film, a polycarbonate film, and a cycloolefin polymer film.

A thickness of the substrate can be appropriately selected according to the purpose of use. For example, in a case the substrate is a glass substrate, the thickness may be 0.3 to 3 mm. In addition, in a case where the substrate is a resin film, the thickness may be 20 μm to 3 mm.

It is also preferable that the substrate has a minimum light transmittance of 80% or more in a wavelength range of 450 to 650 nm. In a case where the substrate satisfies such a condition, it is easy to increase a brightness with a touch panel or the like to which the sensor film is applied.

<Sensor Electrode>

The sensor film according to the embodiment of the present invention includes a sensor electrode.

In FIG. 1, the sensor electrode 104 is an electrode in which a plurality of island-shaped electrodes is electrically connected and extends in one direction, but in the present invention, the form of the sensor electrode is not limited to this embodiment.

For example, the shape of the island-shaped electrode portion is not particularly limited, and may be any of a square, a rectangle, a rhombus, a trapezoid, or a polygonal shape of a pentagon or more, and a square, a rhombus, or a hexagon is preferable from the viewpoint that it is easy to form a close-packed structure.

In addition, in FIG. 1, the sensor electrodes 104 extend in one direction and are arranged in a plurality of directions orthogonal to an extending direction, but the present invention is not limited to this embodiment.

For example, the sensor electrode may be a combination of sensor electrodes (first electrode pattern) arranged in a first direction and sensor electrodes (second electrode pattern) arranged in a second direction so as to intersect the first direction. It is preferable that the first electrode pattern and the second electrode pattern are insulated from each other.

The sensor electrode is preferably a conductive layer (transparent conductive layer) which is transparent.

In a case where the sensor electrode is a transparent conductive layer, a refractive index thereof is not particularly limited, but from the viewpoint that the effects of the present invention are more excellent, the refractive index is preferably 1.70 or more, more preferably 1.70 to 2.30, and still more preferably 1.80 to 2.10.

As a material constituting the sensor electrode (preferably the transparent conductive layer), a known material can be used. For example, the sensor electrode can be constituted of a translucent metal oxide film such as an ITO film, an IZO film, and a SiO₂ film; a metal film of Al, Zn, Cu, Fe, Ni, Cr, Mo, Ag, Au, and the like; and an alloy film of a plurality of metals, such as a copper-nickel alloy.

The material constituting the sensor electrode may be one kind alone or one or more kinds.

A thickness of the sensor electrode (preferably the transparent conductive layer) is preferably 10 to 200 nm.

The sensor electrode conducts (connects) with the lead wire described later.

In conducting the sensor electrode and the lead wire, a connection electrode for conducting the lead wire may or may not be provided on the sensor electrode.

<Lead Wire>

The sensor film according to the embodiment of the present invention includes a lead wire.

The lead wire is not limited as long as it has electrical conductivity, and examples thereof include a metal wire of gold, silver, copper, platinum, and the like, and a carbon fiber wire such as a carbon nanotube, and a metal wire is preferable.

Among these, the lead wire preferably includes one or more metals selected from the group consisting of copper and silver.

In a case where the lead wire includes one or more metals selected from the group consisting of copper and silver, the lead wire contains copper and/or silver in an amount of preferably 50% to 100% by mass, more preferably 90% to 100% by mass, and still more preferably 99% to 100% by mass.

In addition, the lead wire has a connection terminal. It is preferable that the lead wire has a connection terminal on an opposite side of a connecting part with the sensor electrode. The sensor film can be connected to the flexible wiring board and other devices through the connection terminal.

<First Protective Layer>

The first protective layer is a layer disposed on the connection terminal located at one terminal of the lead wire.

From the viewpoint of achieving both electrical connectivity and corrosion resistance, the first protective layer satisfies a relationship represented by the following expression (1), preferably a relationship represented by the following expression (2) and more preferably a relationship represented by the following expression (3).

0 V<D×B≤30.0 V (1)

0.1 V<D×B≤25.0 V (2)

10.0 V<D×B≤20.0 V (3)

Preferred specific examples of the D×B value include 27.0 V, 25.0 V, 21.0 V, 17.5 V, 12.0 V, 7.0 V, 4.0 V, and 0.2 V.

The thickness D of the first protective layer is a thickness of the first protective layer on the connection terminal, and is not particularly limited as long as the relationship of the above expression (1) is satisfied. However, from the viewpoint of more excellent corrosion resistance, the thickness is preferably 0.0003 μm or more, more preferably 0.001 μm or more, still more preferably 0.003 μm or more, and particularly preferably 0.03 μm or more. The upper limit of the thickness D is preferably 1 μm or less, more preferably 0.12 μm or less, and still more preferably 0.08 μm or less.

The dielectric breakdown voltage B of the first protective layer is preferably 1 V/μm or more, more preferably 50 V/μm or more, and still more preferably 100 V/μm or more. The upper limit of the dielectric breakdown voltage B is preferably 5000 V/μm or less, more preferably 1000 V/μm or less, and still more preferably 400 V/μm or less.

Components included in the first protective layer are not particularly limited, and the first protective layer usually includes a resin.

In addition, the first protective layer preferably includes a binder polymer, a polymerizable compound, and a cured substance (crosslinked substance or the like) of a composition including a polymerization initiator. It is also preferable that the first protective layer includes an azole compound.

Details of the components forming the first protective layer will be clarified through the description of a transfer layer described later.

In a case where a transfer layer used to form the first protective layer includes a compound which can be polymerized (crosslinked) in a process of forming the first protective layer, the first protective layer may include a crosslinked substance in which the above-described polymerizable compound is crosslinked.

The first protective layer may be composed of a single layer or may be composed of a plurality of layers.

<Second Protective Layer>

The second protective layer is a layer disposed on at least the sensor electrode or a portion of the lead wire other than the connection terminal.

A thickness of the second protective layer is not particularly limited, but is preferably 0.1 to 100 μm, more preferably 1 to 50 μm, and still more preferably 3 to 20 μm.

The dielectric breakdown voltage B of the second protective layer is preferably 1 V/μm or more, more preferably 50 V/μm or more, and still more preferably 100 V/μm or more. The upper limit of the dielectric breakdown voltage B is preferably 5000 V/μm or less, more preferably 1000 V/μm or less, and still more preferably 400 V/μm or less.

Components included in the second protective layer are not particularly limited, and the second protective layer usually includes a resin.

In addition, the second protective layer preferably includes a binder polymer, a polymerizable compound, and a cured substance (crosslinked substance or the like) of a composition including a polymerization initiator. It is also preferable that the second protective layer includes an azole compound.

The second protective layer may be a layer having substantially the same components as the first protective layer, or may be a layer same as the first protective layer, in which only a thickness is different.

Details of the components forming the second protective layer will be clarified through the description of the transfer layer described later.

In a case where a transfer layer used to form the second protective layer includes a compound which can be polymerized (crosslinked) in a process of forming the second protective layer, the second protective layer may include a crosslinked substance in which the above-described polymerizable compound is crosslinked.

The second protective layer may be composed of a single layer or may be composed of a plurality of layers.

<Other Layers>

The sensor film according to the embodiment of the present invention may include a member other than the above-described members.

For example, the sensor film may include a transparent layer on the substrate. The transparent layer is a layer disposed on the substrate.

The transparent layer may be a transparent resin layer including a resin.

A refractive index of the transparent layer is not particularly limited, but from the viewpoint that the effects of the present invention are more excellent, the refractive index is preferably 1.60 or more, more preferably 1.60 to 1.90, still more preferably 1.60 to 1.70, and particularly preferably 1.60 to 1.65.

A thickness of the transparent layer is preferably 200 nm or less, more preferably 40 to 200 nm, and still more preferably 50 to 100 nm.

<Manufacturing Method of Sensor Film>

A manufacturing method of the sensor film is not particularly limited, and a known method can be adopted.

Examples thereof include a method using a transfer film having a transfer layer (photosensitive resin layer) which can form the first protective layer and/or the second protective layer.

First, a transfer film will be described, and then a manufacturing method of the sensor film using the transfer film will be described.

(Transfer Film)

FIG. 3 is a schematic view showing an example of a configuration of the transfer film. However, the transfer film of the present invention is not limited to the one having the configuration shown in FIG. 3.

In a transfer film 10 shown in FIG. 3, a temporary support 1, a transfer layer 2, and a protective film 3 are laminated in this order.

The transfer film 10 shown in FIG. 3 is composed of the temporary support 1, the transfer layer 2, and the protective film 3, but may have other layers.

In addition, the transfer film 10 shown in FIG. 3 is composed of the temporary support 1, the transfer layer 2, and the protective film 3, but the protective film 3 may be omitted, and for example, the transfer film 10 may be composed of only the temporary support 1 and the transfer layer 2.

Hereinafter, each layer of the transfer film will be described in detail.

Temporary Support

Examples of the temporary support include a glass substrate and a resin film, and a resin film is preferable and a resin film having heat resistance and solvent resistance is more preferable. In addition, as the temporary support, a film which has flexibility and does not generate significant deformation, contraction, or stretching under pressure or under pressure and heating is preferable.

Examples of such a resin film include a polyethylene terephthalate (PET) film, a polyethylene film, a polypropylene film, a cellulose triacetate film, a polystyrene film, and a polycarbonate film. Among these, from the viewpoint that a transparency and heat resistance is more excellent, a polyethylene terephthalate film is preferable.

A surface of the above-described resin film may be mold-released so that it can be easily peeled off from a photosensitive layer later.

From the viewpoint of further improving handleability, the temporary support preferably has a layer in which 10 particles/mm² or more with a diameter of 5 μm or more are present on a surface opposite to the side where the transfer layer is formed, and it is more preferable that 10 to 120 particles/mm² are present. The upper limit value of the diameter of the above-described particles is, for example, 10 μm or less.

From the viewpoint that a mechanical strength is more excellent, a thickness of the temporary support is preferably 5 μm or more, more preferably 10 μm or more, and still more preferably 15 μm or more. By using a temporary support having a thickness of the above-described numerical value or more, a tearing of the temporary support in a step of forming the transfer layer, an exposing step, a developing step, and a step of peeling off the temporary support from the transfer film after transfer, which will be described later, is suppressed.

In addition, from the viewpoint that a resolution of a conductive pattern is more excellent in a case where the transfer layer is irradiated with actinic ray through the temporary support, the thickness of the temporary support is preferably 300 μm or less, more preferably 200 μm or less, and still more preferably 100 μm or less.

From the above-described viewpoints, the thickness of the temporary support is preferably 5 to 300 μm, more preferably 10 to 200 μm, and still more preferably 15 to 100 μm.

From the viewpoint that an exposure sensitivity of the transfer layer and the resolution of the conductive pattern are more excellent, a haze value of the temporary support is preferably 0.01% to 5.0%, more preferably 0.01% to 3.0%, still more preferably 0.01% to 2.0%, and particularly preferably 0.01% to 1.5%.

The haze value can be measured by a method in accordance with JIS K 7105 (optical characteristics test method for plastics) using a commercially available turbidity meter, for example, NDH-1001DP (manufactured by NIPPON DENSHOKU INDUSTRIES Co., LTD., product name) or the like.

In the temporary support, from the viewpoint that the exposure sensitivity of the transfer layer and the resolution of the conductive pattern are more excellent, a transmittance of light having a wavelength of the actinic ray to be irradiated (preferably, a wavelength of 365 nm) is preferably 50% or more, more preferably 60% or more, and still more preferably 70% or more.

The transmittance of the layer included in the transfer film is a ratio of an intensity of emitted light emitted through the layer to an intensity of incidence ray in a case where light is incident in a direction perpendicular to a main surface of the layer (thickness direction), and is measured using MCPD Series manufactured by OTSUKA ELECTRONICS Co., Ltd.

In addition, it is preferable that the film used as the temporary support does not have deformation such as wrinkles or scratches.

From the viewpoint that a pattern formability during pattern exposure through the temporary support and a transparency of the temporary support are more excellent, it is preferable that the number of fine particles, foreign substances, and defects included in the temporary support is small. In a surface of the temporary support opposite to the side having the transfer layer, the number of fine particles having a diameter of 1 μm or more, foreign substances, and defects is preferably 50 pieces/10 mm² or less, more preferably 10 pieces/10 mm² or less, and still more preferably 3 pieces/10 mm² or less.

Transfer Layer (Photosensitive Resin Layer)

The transfer layer is a layer which can eventually become the first protective layer and the second protective layer.

For example, the transfer layer is preferably a layer including a resin. The resin is preferably a resin which functions as a binder polymer.

The transfer layer may be a layer including at least a polymerizable monomer and a resin, and is preferably a layer which is cured (crosslinked) by applying light energy. The transfer layer also preferably includes a polymerization initiator or a compound which can react with an acid by heating.

The transfer layer is preferably photocurable. The transfer layer may have thermosetting property.

A thickness of the transfer layer is not particularly limited, and for example, may be adjusted to the same degree as the thickness of the second protective layer.

Transfer Layer A Layer

In addition, the transfer layer may be a single layer or may be composed of two or more layers.

The transfer layer preferably has at least a transfer layer A layer described below. In other words, the first protective layer and/or the second protective layer preferably has a layer derived from the transfer layer A layer.

The transfer layer A layer preferably functions as a photosensitive resin layer.

Binder Polymer

The transfer layer A layer may include a binder polymer. The binder polymer is a resin which can function as a binder polymer. As the binder polymer, an alkali-soluble resin exhibiting alkali solubility is preferable.

In the present disclosure, the “alkali-soluble” means that the dissolution rate obtained by the following method is 0.01 μm/sec or more.

A propylene glycol monomethyl ether acetate solution having a concentration of a target compound (for example, a resin) of 25% by mass is applied to a glass substrate, and then heated in an oven at 100° C. for 3 minutes to obtain a coating film (thickness: 2.0 μm) of the target compound. The above-described coating film is immersed in a 1% by mass aqueous solution of sodium carbonate (liquid temperature: 30° C.), thereby obtaining the dissolution rate (μm/sec) of the above-described coating film.

In a case where the target compound is not dissolved in propylene glycol monomethyl ether acetate, the target compound is dissolved in an organic solvent (for example, tetrahydrofuran, toluene, and ethanol) having a boiling point of lower than 200° C., other than propylene glycol monomethyl ether acetate.

The alkali-soluble resin can be appropriately selected from polymers having at least one group which promotes the alkali solubility in the molecule. In addition, it is also preferable that the alkali-soluble resin is a linear organic high-molecular-weight polymer. Examples of the group which promotes alkali solubility (acid group) include a carboxyl group, a phosphoric acid group, and a sulfonic acid group, and a carboxyl group is preferable.

As the alkali-soluble resin, from the viewpoint of developability, a resin having an acid value of 60 mgKOH/g or more is preferable. The above-described acid value is preferably 60 to 200 mgKOH/g and more preferably 60 to 150 mgKOH/g.

In the present specification, the acid value of the resin is a value measured by a titration method specified in JIS K0070 (1992).

A weight-average molecular weight of the alkali-soluble resin is preferably 5,000 or more and more preferably 10,000 or more. The upper limit value of the weight-average molecular weight of the alkali-soluble resin is not particularly limited, and may be 100,000.

In addition, from the viewpoint that it is easy to form a strong film by reacting with a crosslinking component to be thermally crosslinked, the alkali-soluble resin is preferably a resin having a carboxyl group.

From the viewpoint that it is easy to use as the alkali-soluble resin, the binder polymer is preferably a (meth)acrylic resin.

The (meth)acrylic resin is preferably a resin having a constitutional unit derived from at least one of (meth)acrylic acid or (meth)acrylic acid ester. A content of the constitutional unit derived from at least one of (meth)acrylic acid or (meth)acrylic acid ester is preferably 20 to 100 mol % and more preferably 40 to 100 mol % with respect to all constitutional units of the binder polymer.

Among these, the binder polymer preferably has a constitutional unit derived from (meth)acrylic acid. The content of the constitutional unit derived from (meth)acrylic acid is preferably 5 to 50 mol % and more preferably 10 to 35 mol % with respect to all constitutional units of the binder polymer.

In addition, it is also preferable that the binder polymer has a constitutional unit having a polymerizable group (a (meth)acryloyl group, an ethylenically unsaturated group such as an allyl group, and/or the like). A content of the constitutional unit having a polymerizable group is preferably 5 to 90 mol % and more preferably 10 to 85 mol % with respect to all constitutional units of the binder polymer.

The binder polymer preferably has at least one of a monocyclic or polycyclic alicyclic structure, a linear or branched chain structure, or an aromatic structure.

Examples of the alicyclic structure include a tricyclodecane ring, a cyclohexane ring, a cyclopentane ring, a norbornane ring, and an isophorone ring.

Examples of a monomer for forming the constitutional unit having an alicyclic structure include dicyclopentanyl (meth)acrylate, cyclohexyl (meth)acrylate, and isobornyl (meth)acrylate.

Among these, it is also preferable that the binder polymer has a structural unit having a tricyclodecane skeleton (preferably a tricyclo[5.2.1.0^{2,6}]decane skeleton). Examples of the above-described structural unit include a structural unit based on (meth)acrylic acid ester having a tricyclodecanyl group (preferably, a tricyclo[5.2.1.0^{2,6}]decaneyl group) in a side chain (dicyclopentanyl (meth)acrylic acid and the like). It is also preferable that the above-described constitutional unit does not have an acid group and/or a polymerizable group.

A content of the constitutional unit having an alicyclic structure is preferably 1 to 40 mol % and more preferably 5 to 25 mol % with respect to all constitutional units of the binder polymer.

Examples of a monomer for forming the constitutional unit having a chain structure include (meth)acrylic acid alkyl esters, and examples of the alkyl group include alkyl groups having 1 to 12 carbon atoms.

Specific examples thereof include methyl (meth)acrylate, ethyl (meth)acrylate, propyl (meth)acrylate, butyl (meth)acrylate, pentyl (meth)acrylate, hexyl (meth)acrylate, heptyl (meth)acrylate, octyl (meth)acrylate, 2-ethylhexyl (meth)acrylate, nonyl (meth)acrylate, decyl (meth)acrylate, undecyl (meth)acrylate, and dodecyl (meth)acrylate. As the (meth)acrylic acid ester, (meth)acrylic acid alkyl ester having an alkyl group having 1 to 4 carbon atoms is preferable, and methyl (meth)acrylate or ethyl (meth)acrylate is more preferable.

In a case where the binder polymer has the constitutional unit having a chain structure, from the viewpoint that the effects of the present invention are more excellent, the content of the constitutional unit having a chain structure is preferably 1% to 90% by mass, more preferably 10% to 70% by mass, and still more preferably 20% to 60% by mass with respect to the all constitutional units of the binder polymer.

From the viewpoint that the effects of the present invention are more excellent, the binder polymer preferably has an aromatic ring structure, and more preferably has a constitutional unit having an aromatic ring structure.

Examples of a monomer forming the constitutional unit having an aromatic ring structure include a monomer having an aralkyl group, styrene, and a polymerizable styrene derivative (for example, methylstyrene, vinyltoluene, tert-butoxystyrene, acetoxystyrene, 4-vinylbenzoic acid, styrene dimer, and styrene trimer). Among these, a monomer having an aralkyl group or styrene is preferable.

Examples of the aralkyl group include a substituted or unsubstituted phenylalkyl group (excluding a benzyl group), and a substituted or unsubstituted benzyl group, and a substituted or unsubstituted benzyl group is preferable.

Examples of a monomer having the phenylalkyl group include phenylethyl (meth)acrylate.

Examples of a monomer having the benzyl group include (meth)acrylates having a benzyl group, such as benzyl (meth)acrylate and chlorobenzyl (meth)acrylate; and vinyl monomers having a benzyl group, such as vinylbenzyl chloride and vinylbenzyl alcohol. Among these, benzyl (meth)acrylate is preferable.

In addition, from the viewpoint that the effects of the present invention are more excellent, the binder polymer more preferably has a constitutional unit represented by Formula (S) (constitutional unit derived from styrene).

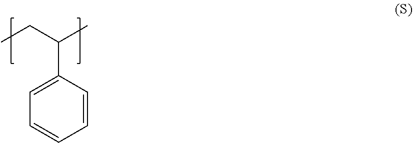

In a case where the binder polymer has the constitutional unit having an aromatic ring structure, from the viewpoint that the effects of the present invention are more excellent, the content of the constitutional unit having an aromatic ring structure is preferably 5% to 90% by mass, more preferably 10% to 70% by mass, and still more preferably 20% to 60% by mass with respect to the all constitutional units of the binder polymer.

In addition, from the viewpoint that the effects of the present invention are more excellent, the content of the constitutional unit having an aromatic ring structure in the binder polymer is preferably 5 to 70 mol %, more preferably 10 to 60 mol %, and still more preferably 20 to 60 mol % with respect to all constitutional units of the binder polymer.

It is also preferable that the binder polymer has a constitutional unit which does not correspond to any of the above-described constitutional units (for example, a structural unit having no acid group, polymerizable group, and tricyclodecane skeleton). A content of such a constitutional unit is preferably 10 to 85 mol % and more preferably 30 to 70 mol % with respect to all constitutional units of the binder polymer.

As the binder polymer, from the viewpoint that the effects of the present invention are more excellent, polymers shown below are more preferable. Content ratios (a to d) and weight-average molecular weights Mw of each of the constitutional units shown below can be appropriately changed according to the purpose.

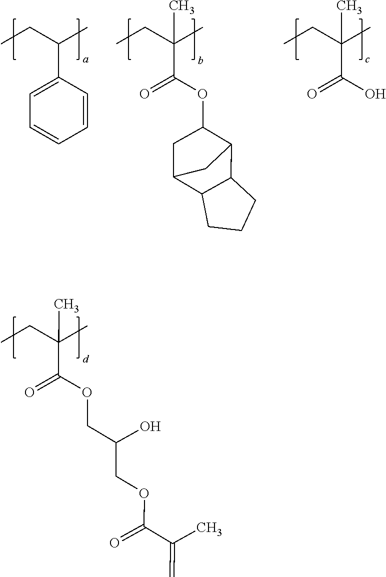

In the above formulae, it is preferable that a is 20% to 60% by mass, b is 10% to 50% by mass, c is 5.0% to 25% by mass, and d is 10% to 50% by mass.

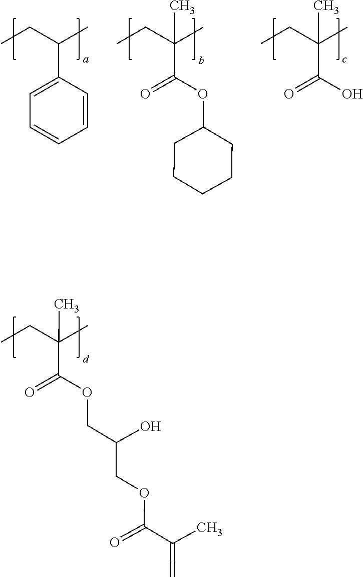

In the above formulae, it is preferable that a is 20% to 60% by mass, b is 10% to 50% by mass, c is 5.0% to 25% by mass, and d is 10% to 50% by mass.

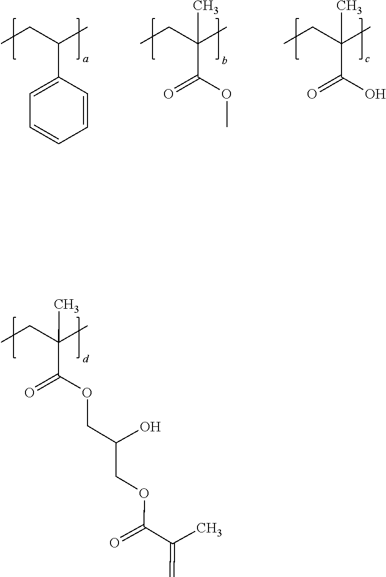

In the above formulae, it is preferable that a is 30% to 65% by mass, b is 1.0% to 20% by mass, c is 5.0% to 25% by mass, and d is 10% to 50% by mass.

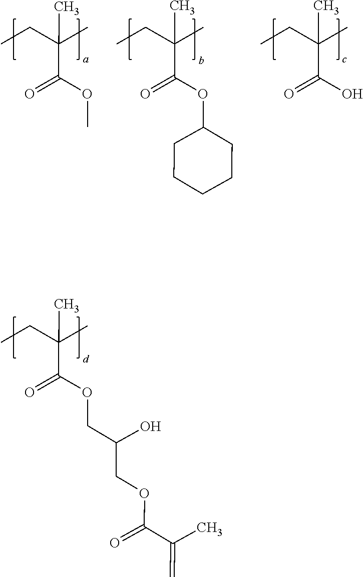

In the above formulae, it is preferable that a is 1.0% to 20% by mass, b is 20% to 60% by mass, c is 5.0% to 25% by mass, and d is 10% to 50% by mass.

A content of the binder polymer (preferably, the alkali-soluble resin) is not particularly limited, but is preferably 1% to 80% by mass and more preferably 5% to 60% by mass with respect to the total mass of the transfer layer A layer.

The resin may be used alone or in combination of two or more thereof.

In a case where the binder polymer has a constitutional unit having a polymerizable group, the binder polymer may be a crosslinked substance in a case where the first protective layer and/or the second protective layer is formed from the transfer layer. In the layer derived from the transfer layer A layer of the first protective layer and/or the second protective layer, a suitable range of the total content of the binder polymer and a portion derived from the binder polymer constituting the crosslinked substance is the same as the suitable content of the binder polymer in the total mass of the transfer layer A layer.

Polymerizable Compound

The transfer layer A layer may include a polymerizable compound.

The polymerizable compound is preferably a component different from the above-described binder polymer, and for example, is preferably a compound having a molecular weight (a weight-average molecular weight in a case of having a molecular weight distribution) of less than 5000 and also preferably a polymerizable monomer.

As the polymerizable compound, a polymerizable compound having an ethylenically unsaturated group is preferable, and a photopolymerizable compound having an ethylenically unsaturated group is more preferable. The polymerizable compound preferably has at least one ethylenically unsaturated group as a photopolymerizable group. As the polymerizable compound, a compound having a (meth)acryloyl group is preferable.

As the polymerizable compound, a polyfunctional polymerizable compound having two or more ethylenically unsaturated groups is preferable. As the polyfunctional polymerizable compound, a compound having two ethylenically unsaturated groups or a compound having at least three ethylenically unsaturated groups is preferable, and a compound having two (meth)acryloyl groups or a compound having at least three (meth)acryloyl groups is more preferable.

In addition, the fact that at least one of the polymerizable compounds includes a carboxyl group is also preferable from the viewpoint that the carboxyl group in the above-described resin and the carboxyl group of the polymerizable compound form a carboxylic acid anhydride to enhance wet heat resistance.

Examples of the polymerizable compound having a carboxyl group include ARONIX (registered trademark) TO-2349 (manufactured by Toagosei Co., Ltd.), ARONIX (registered trademark) M-520 (manufactured by Toagosei Co., Ltd.), and ARONIX (registered trademark) M-510 (manufactured by Toagosei Co., Ltd.).

In addition, it is also preferable that at least one of the polymerizable compounds is a polymerizable compound having a tricyclodecane skeleton (preferably, a tricyclo[5.2.1.0^{2,6}]decane skeleton).

Examples of such a polymerizable compound include a compound represented by General Formula (TD).

X[—(CH₂)ₛ—(OR)ₜ—O-Q]ᵤ (TD)

In Group Formula (TD), X represents a tricyclodecane ring group (preferably, a tricyclo[5.2.1.0^{2,6}]decane ring group).

s represents an integer of 0 to 2, and is preferably 0.

t represents an integer of 0 to 10, and is preferably 1.

u represents an integer of 1 to 6, and is preferably 2.

R represents an alkylene group having 1 to 5 carbon atoms. The above-described alkylene group may be linear or branched.

Q represents a (meth)acryloyl group.

In General Formula (TD), in a case where there is a plurality of groups or integers represented by the same code, the groups or integers represented by the same code may be the same or different from each other.

Examples of a commercially available product of the compound represented by General Formula (TD) include tricyclodecane dimethanol diacrylate (product name: NK ESTER A-DCP, manufactured by Shin-Nakamura Chemical Co., Ltd.), and tricyclodecane dimethanol dimethacrylate (product name: NK ESTER DCP, manufactured by Shin-Nakamura Chemical Co., Ltd.).

It is also preferable that at least one of the polymerizable compounds is a urethane (meth)acrylate compound (preferably, a tri- or higher functional urethane (meth)acrylate compound).

Examples of the tri- or higher functional urethane (meth)acrylate compound include 8UX-015A (manufactured by Taisei Fine Chemical Co., Ltd.), NK ESTER UA-32P (manufactured by Shin-Nakamura Chemical Co., Ltd.), and NK ESTER UA-1100H (manufactured by Shin-Nakamura Chemical Co., Ltd.).

A molecular weight of the polymerizable compound is preferably 200 to 3000, more preferably 250 to 2600, and still more preferably 280 to 2200.

The content of the polymerizable compound is not particularly limited, but is preferably 1% to 50% by mass and more preferably 2% to 40% by mass with respect to the total mass of the transfer layer A layer.

In a case of using a polyfunctional polymerizable compound, a content of the polyfunctional polymerizable compound is preferably 10% to 90% by mass and more preferably 20% to 85% by mass with respect to the total mass of all polymerizable compounds included in the transfer layer A layer.

The polymerizable compound may be used alone or in combination of two or more thereof.

As the polymerizable compound, from the viewpoint of enhancing wet heat resistance, it is preferable to include the compound represented by General Formula (TD) and the compound having at least three (meth)acryloyl groups.

The polymerizable compound may be a crosslinked substance in a case where the first protective layer and/or the second protective layer is formed from the transfer layer. In the layer derived from the transfer layer A layer of the first protective layer and/or the second protective layer, a suitable range of the total content of the polymerizable compound and a portion derived from the polymerizable compound constituting the crosslinked substance is the same as the suitable content of the polymerizable compound in the total mass of the transfer layer A layer.

Compound Having Tricyclodecane Skeleton

The transfer layer A layer may include a compound having a tricyclodecane skeleton.

The compound having a tricyclodecane skeleton may be in a form of the binder polymer, in a form of the polymerizable compound, or a compound which does not correspond to any of these.

Examples of the compound having a tricyclodecane skeleton as a form of the binder polymer include the binder polymer having a structural unit having the above-described tricyclodecane skeleton.

Examples of the compound having a tricyclodecane skeleton as a form of the polymerizable compound include the polymerizable compound having the above-described tricyclodecane skeleton.

The total content of the compound having a tricyclodecane skeleton is preferably 1% to 80% by mass and more preferably 5% to 60% by mass with respect to the total mass of the transfer layer A layer.

The compound having a tricyclodecane skeleton may be used alone or in combination of two or more thereof.

In a case where the compound having a tricyclodecane skeleton has a polymerizable group, the compound having a tricyclodecane skeleton may be a crosslinked substance in a case where the first protective layer and/or the second protective layer is formed from the transfer layer. In the layer derived from the transfer layer A layer of the first protective layer and/or the second protective layer, a suitable range of the total content of the compound having a tricyclodecane skeleton and a portion derived from the compound having a tricyclodecane skeleton constituting the crosslinked substance is the same as the suitable content of the compound having a tricyclodecane skeleton in the total mass of the transfer layer A layer.

Polymerization Initiator

The transfer layer A layer may include a polymerization initiator.

The polymerization initiator preferably includes at least a photopolymerization initiator.

The photopolymerization initiator preferably includes at least one selected from the group consisting of an oxime-based photopolymerization initiator, an alkylphenone-based photopolymerization initiator, a thioxanthene-based photopolymerization initiator, and an N-phenylglycine-based photopolymerization initiator.

In a case where the transfer layer A layer includes a polymerization initiator, a content of the polymerization initiator is preferably 0.01% to 10% by mass and more preferably 0.05% to 5% by mass with respect to the total mass of the transfer layer A layer.

The polymerization initiator may be used alone or in combination of two or more thereof.

The photopolymerization initiator preferably includes an oxime-based photopolymerization initiator and an alkylphenone-based photopolymerization initiator. The photopolymerization initiator also preferably includes an alkylphenone-based photopolymerization initiator and a thioxanthene-based photopolymerization initiator.

In addition, examples of the photopolymerization initiator also include polymerization initiators described in paragraphs 0031 to 0042 of JP2011-95716A and paragraphs 0064 to 0081 of JP2015-014783A.

Examples of a commercially available product of the photopolymerization initiator include 1-[4-(phenylthio)phenyl]-1,2-octanedione-2-(O-benzoyloxime) [product name: IRGACURE (registered trademark) OXE-01, manufactured by BASF SE], 1-[9-ethyl-6-(2-methylbenzoyl)-9H-carbazol-3-yl]ethanone-1-(0-acetyloxime) [product name: IRGACURE (registered trademark) OXE-02, manufactured by BASF SE], [8-[5-(2,4,6-trimethylphenyl)-11-(2-ethylhexyl)-11H-benzo[a]carbazoyl][2-(2,2,3,3-tetrafluoro propoxy)phenyl]methanone-(O-acetyloxime) [product name: IRGACURE (registered trademark) OXE-03, manufactured by BASF SE], 1-[4-[4-(2-benzofuranylcarbonyl)phenyl]thio]phenyl]-4-methylpentanone-1-(0-acetyloxime) [product name: IRGACURE (registered trademark) OXE-04, manufactured by BASF SE], 2-(dimethylamino)-2-[(4-methylphenyl)methyl]-1-[4-(4-morpholinyl)phenyl]-1-butanone [product name: IRGACURE (registered trademark) 379EG, manufactured by BASF SE], 2-methyl-1-(4-methylthiophenyl)-2-morpholinopropan-1-one [product name: IRGACURE (registered trademark) 907, manufactured by BASF SE], 2-hydroxy-1-{4-[4-(2-hydroxy-2-methylpropionyl)benzyl]phenyl}-2-methylpropan-1-one [product name: IRGACURE (registered trademark) 127, manufactured by BASF SE], 2-benzyl-2-dimethylamino-1-(4-morpholinophenyl)butanone-1 [product name: IRGACURE (registered trademark) 369, manufactured by BASF SE], 2-hydroxy-2-methyl-1-phenylpropan-1-one [product name: IRGACURE (registered trademark) 1173, manufactured by BASF SE], 1-hydroxy cyclohexyl phenyl ketone [product name: IRGACURE (registered trademark) 184, manufactured by BASF SE], 2,2-dimethoxy-1,2-diphenylethan-1-one (product name: IRGACURE 651, manufactured by BASF SE], an oxime ester-based product [product name: Lunar (registered trademark) 6, manufactured by DKSH Management Ltd.], 1-[4-(phenylthio)phenyl]-3-cyclopentylpropan-1,2-dione-2-(O-benzoyloxime) (product name: TR-PBG-305, manufactured by TRONLY), 1,2-propanedione, 3-cyclohexyl-1-[9-ethyl-6-(2-furanylcarbonyl)-9H-carbazole-3-yl]-, 2-(O-acetyloxime) (product name: TR-PBG-326, manufactured by TRONLY), 3-cyclohexyl-1-(6-(2-(benzoyloxyimino)hexanoyl)-9-ethyl-9H-carbazole-3-yl)-propan-1,2-dio ne-2-(O-benzoyloxime) (product name: TR-PBG-391, manufactured by TRONLY), and APi-307 (1-(biphenyl-4-yl)-2-methyl-2-morpholinopropan-1-one, manufactured by Shenzhen UV-ChemTech Co., Ltd.).

The polymerization initiator may be chemically changed by light reception and/or heating in a case where the first protective layer and/or the second protective layer is formed from the transfer layer.

Compound which can React with Acid by Heating

The transfer layer A layer may include a compound which can react with an acid by heating.

Examples of the compound which can react with an acid by heating include a carboxylic acid compound, an alcohol compound, an amine compound, a blocked isocyanate compound, and an epoxy compound, and a blocked isocyanate compound is preferable.

In addition, the number of groups of the compound which can react with an acid by heating is preferably 1 to 10, more preferably 1 to 6, and still more preferably 1 to 4.

The blocked isocyanate compound refers to a “compound having a structure in which the isocyanate group of isocyanate is protected (masked) with a blocking agent”.

An initial glass transition temperature (Tg) of the blocked isocyanate compound is preferably −40° C. to 10° C. and more preferably −30° C. to 0° C.

A dissociation temperature of the blocked isocyanate compound is preferably 100° C. to 160° C. and more preferably 130° C. to 150° C.

The dissociation temperature of blocked isocyanate in the present specification is a “temperature at an endothermic peak accompanied with a deprotection reaction of blocked isocyanate, in a case where the measurement is performed by differential scanning calorimetry (DSC) analysis using a differential scanning calorimeter (manufactured by Seiko Instruments Inc., DSC6200)”.

Examples of the blocking agent having a dissociation temperature at 100° C. to 160° C. include a pyrazole compound (3,5-dimethylpyrazole, 3-methylpyrazole, 4-bromo-3,5-dimethylpyrazole, 4-nitro-3,5-dimethylpyrazole, or the like), an active methylene compound (diester malonate (dimethyl malonate, diethyl malonate, di n-butyl malonate, di-2-ethylhexyl malonate)), a triazole compound (1,2,4-triazole or the like), and an oxime compound (compound having a structure represented by —C(═N—OH)— in a molecule such as formaldoxime, acetoaldoxime, acetoxime, methyl ethyl ketoxime, or cyclohexanone oxime).

In addition, from the viewpoint of improving brittleness of the film and improving adhesion force to the transferred body, it is preferable that the blocked isocyanate compound has an isocyanurate structure.

Examples of a commercially available product of the blocked isocyanate compound include Karenz AOI-BM, Karenz MOI-BM, and Karenz MOI-BP (all of which are manufactured by SHOWA DENKO K.K.), and DURANATE WT32-B75P and DURANATE TPA-B80E (all of which are manufactured by Asahi Kasei Corporation).

A molecular weight of the compound which can react with an acid by heating (preferably, the blocked isocyanate compound) is preferably 200 to 3000, more preferably 250 to 2600, and still more preferably 280 to 2200.

A content of the compound which can react with an acid by heating (preferably, the blocked isocyanate compound) is not particularly limited, but is preferably 1% to 30% by mass and more preferably 5% to 20% by mass with respect to the total mass of the transfer layer A layer.

The compound which can react with an acid by heating (preferably, the blocked isocyanate compound) may be used alone or in combination of two or more thereof.

The compound which can react with an acid by heating may be chemically changed or may form a crosslinked substance with other compounds in a case where the first protective layer and/or the second protective layer is formed from the transfer layer. In the layer derived from the transfer layer A layer of the first protective layer and/or the second protective layer, a suitable range of the total content of the compound which can react with an acid by heating, a compound obtained by chemically changing the above-described compound, and a portion derived from the above-described compound in the crosslinked substance including the above-described compound as a constituent element constituting the crosslinked substance is the same as the suitable content of the compound which can react with an acid by heating in the total mass of the transfer layer A layer.

Azole Compound

The transfer layer A layer may include an azole compound.

In the present specification, the “azole compound” means a compound having an azole structure (five-membered ring structure which includes one or more nitrogen atoms as a ring-membered atom and exhibits aromaticity) and having a molecular weight of 1000 or less.

The azole compound can act as a rust inhibitor.

It is preferable that the azole compound is one or more compounds selected from the group consisting of triazoles, tetrazoles, imidazoles, and thiadiazoles.

Examples of the above-described triazoles include benzotriazole, 1H-benzotriazole-1-acetonitrile, benzotriazole-5-carboxylic acid, 1H-benzotriazole-1-methanol, carboxybenzotriazole, triazoles including a mercapto group, such as 3-mercaptotriazole, and triazoles including an amino group, such as 3-amino-5-mercaptotriazole.

Examples of the above-described tetrazoles include a compound represented by General Formula (D-1).

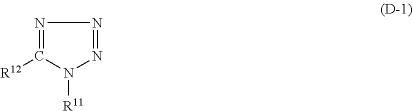

R¹¹ and R¹² in General Formula (D-1) each independently represent hydrogen, an alkyl group having 1 to 20 carbon atoms, an amino group, a mercapto group, and a carboxymethyl group.

Examples of the alkyl group include a methyl group, an ethyl group, and a propyl group.

Specific examples of the tetrazoles represented by General Formula (D-1) include 1H-tetrazole, 5-amino-1H-tetrazole, 5-methyl-1H-tetrazole, 1-methyl-5-ethyl-tetrazole, 1-methyl-5-mercapto-tetrazole, and 1-carboxymethyl-5-mercapto-tetrazole.

The tetrazoles may be a water-soluble salt of the tetrazoles represented by General Formula (D-1). Specific examples thereof include alkali metal salts of 1-carboxymethyl-5-mercapto-tetrazole including sodium, potassium, lithium, or the like.

Examples of the above-described imidazoles include 2-methylimidazole, 2-phenylimidazole, 2-formylimidazole, 4-formylimidazole, 2-phenyl-4-methylimidazole, imidazole-4,5-dicarboxylic acid, benzimidazole, 2-mercaptobenzimidazole.

Examples of the above-described thiadiazoles include 2-amino-5-mercapto-1,3,4-thiadiazole and 2,1,3-benzothiadiazole.

The content of the azole compound is not particularly limited, but is preferably 1% to 80% by mass and more preferably 5% to 60% by mass with respect to the total mass of the transfer layer A layer.

The azole compound may be used alone or in combination of two or more thereof.

In the layer derived from the transfer layer A layer of the first protective layer and/or the second protective layer, a suitable range of the total content of the azole compound is the same as the suitable content of the azole compound in the total mass of the transfer layer A layer.

Surfactant

The transfer layer A layer may include a surfactant.

Examples of the surfactant include surfactants described in paragraph [0017] of JP4502784B and paragraphs [0060] to [0071] of JP2009-237362A.

As the surfactant, a nonionic surfactant, a fluorine-based surfactant, or a silicone-based surfactant is preferable.

Examples of a commercially available product of the fluorine-based surfactant include: MEGAFACE F-171, F-172, F-173, F-176, F-177, F-141, F-142, F-143, F-144, F-437, F-475, F-477, F-479, F-482, F-551-A, F-552, F-554, F-555-A, F-556, F-557, F-558, F-559, F-560, F-561, F-565, F-563, F-568, F-575, F-780, EXP, MFS-330, MFS-578, MFS-579, MFS-586, MFS-587, R-41, R-41-LM, R-01, R-40, R-40-LM, RS-43, TF-1956, RS-90, R-94, RS-72-K, and DS-21 (all of which are manufactured by DIC Corporation); FLUORAD FC430, FC431, and FC171 (all of which are manufactured by Sumitomo 3M Ltd.); SURFLON S-382, SC-101, SC-103, SC-104, SC-105, SC-1068, SC-381, SC-383, S-393, and KH-40 (all of which are manufactured by Asahi Glass Co., Ltd.); and POLYFOX PF636, PF656, PF6320, PF6520, and PF7002 (all of which are manufactured by OMNOVA Solutions Inc.); FTERGENT 710FL, 710FM, 610FM, 601AD, 601ADH2, 602A, 215M, 245F, 251, 212M, 250, 209F, 222F, 208G, 710LA, 710FS, 730LM, 650AC, 681, and 683 (all of which are manufactured by NEOS COMPANY LIMITED).

In addition, as the fluorine-based surfactant, an acrylic compound, which has a molecular structure having a functional group containing a fluorine atom and in which, by applying heat to the molecular structure, the functional group containing a fluorine atom is broken to volatilize a fluorine atom, can also be suitably used. Examples of such a fluorine-based surfactant include MEGAFACE DS series manufactured by DIC Corporation (The Chemical Daily (Feb. 22, 2016) and Nikkei Business Daily (Feb. 23, 2016)), for example, MEGAFACE DS-21. In addition, as the fluorine-based surfactant, a polymer of a fluorine atom-containing vinyl ether compound having a fluorinated alkyl group or a fluorinated alkylene ether group, and a hydrophilic vinyl ether compound is also preferably used.

In addition, as the fluorine-based surfactant, a block polymer can also be used.

In addition, as the fluorine-based surfactant, a fluorine-containing polymer compound including a constitutional unit derived from a (meth)acrylate compound having a fluorine atom and a constitutional unit derived from a (meth)acrylate compound having 2 or more (preferably 5 or more) alkyleneoxy groups (preferably ethyleneoxy groups or propyleneoxy groups) can also be preferably used.

In addition, as the fluorine-based surfactant, a fluorine-containing polymer having an ethylenically unsaturated bond in the side chain can also be used. Examples thereof include MEGAFACE RS-101, RS-102, RS-718K, and RS-72-K (all of which are manufactured by DIC Corporation).

As the fluorine-based surfactant, from the viewpoint of improving environmental suitability, a surfactant derived from a substitute material for a compound having a linear perfluoroalkyl group having 7 or more carbon atoms, such as perfluorooctanoic acid (PFOA) and perfluorooctanesulfonic acid (PFOS), is preferable.

Examples of the nonionic surfactant include glycerol, trimethylolpropane, trimethylolethane, an ethoxylate and propoxylate thereof (for example, glycerol propoxylate or glycerol ethoxylate), polyoxyethylene lauryl ether, polyoxyethylene stearyl ether, polyoxyethylene oleyl ether, polyoxyethylene octylphenyl ether, polyoxyethylene nonylphenyl ether, polyethylene glycol dilaurate, polyethylene glycol distearate, sorbitan fatty acid esters, PLURONIC (registered trademark) L10, L31, L61, L62, 10R5, 17R2, and 25R2 (all of which are manufactured by BASF SE), TETRONIC 304, 701, 704, 901, 904, and 150R1 (all of which are manufactured by BASF SE), SOLSPERSE 20000 (manufactured by Lubrizol Corporation), NCW-101, NCW-1001, and NCW-1002 (all of which are manufactured by FUJIFILM Wako Pure Chemical Corporation), PIONIN D-6112, D-6112-W, and D-6315 (all of which are manufactured by Takemoto Oil & Fat Co., Ltd.), and OLFINE E1010 and SURFYNOL 104, 400, and 440 (all of which are manufactured by Nissin Chemical Co., Ltd.).

Examples of the silicone-based surfactant include a linear polymer consisting of a siloxane bond and a modified siloxane polymer with an organic group introduced in the side chain or the terminal.

Specific examples of the surfactant include DOWSIL 8032 ADDITIVE, TORAY SILICONE DC3PA, TORAY SILICONE SH7PA, TORAY SILICONE DCllPA, TORAY SILICONE SH21PA, TORAY SILICONE SH28PA, TORAY SILICONE SH29PA, TORAY SILICONE SH30PA, and TORAY SILICONE SH8400 (all of which are manufactured by Dow Corning Toray Co., Ltd.), X-22-4952, X-22-4272, X-22-6266, KF-351A, K354L, KF-355A, KF-945, KF-640, KF-642, KF-643, X-22-6191, X-22-4515, KF-6004, KP-341, KF-6001, and KF-6002 (all of which are manufactured by Shin-Etsu Silicone Co., Ltd.), F-4440, TSF-4300, TSF-4445, TSF-4460, and TSF-4452 (all of which are manufactured by Momentive Performance Materials Co., Ltd.), and BYK307, BYK323, and BYK330 (all of which are manufactured by BYK Chemie). A content of the surfactant is not particularly limited, but is preferably 0.01% to 10% by mass and more preferably 0.05% to 5% by mass with respect to the total mass of the transfer layer A layer.

The surfactant may be used alone or in combination of two or more thereof.

In the layer derived from the transfer layer A layer of the first protective layer and/or the second protective layer, a suitable range of the total content of the surfactant is the same as the suitable content of the surfactant in the total mass of the transfer layer A layer.

The transfer layer A layer may include a component other than the above-described components.

Examples of other components include a sensitizer, a polymerization inhibitor, and particles.

A thickness of the transfer layer A layer is not particularly limited, but is preferably 0.1 to 100 μm, more preferably 1 to 50 μm, and still more preferably 3 to 20 μm.

Examples of a preferred thickness include 8.0 μm, 5.8 μm, 4.2 μm, and 3.0 μm.

Transfer Layer B Layer

The transfer layer preferably has a transfer layer B layer in addition to the transfer layer A layer.

A mutual positional relationship between the transfer layer A layer and the transfer layer B layer is not limited. Among these, it is preferable that the transfer layer A layer is disposed so as to be located on the surface side (opposite side of the substrate) after transfer.

It is not necessary that the transfer layer B layer itself is a layer which functions as a photosensitive resin layer, and by imparting the transfer layer A layer a function as the photosensitive resin layer, the transfer layer as a whole may have the property as the photosensitive resin layer.

Examples of components which can be contained in the transfer layer B layer include the same components which can be contained in the transfer layer A layer.

Among these, the transfer layer B layer preferably includes a binder polymer. In addition, from the viewpoint of adjusting refractive index and light transmittance, the transfer layer B layer also preferably includes particles.

As the particles, metal oxide particles are preferable.

The type of the metal oxide particles is not particularly limited, and known metal oxide particles can be used. From the viewpoint that it is easy to control the transparency and the refractive index, it is preferable to include at least one of zirconium oxide particles (ZrO₂ particles), Nb₂O₅ particles, titanium oxide particles (TiO₂ particles), or silicon dioxide particles (SiO₂ particles). Among these, zirconium oxide particles or titanium oxide particles are more preferable, and zirconium oxide particles are still more preferable.

From the viewpoint of optical performance such as a haze, an average primary particle diameter of the particles is preferably 100 nm or less, more preferably 50 nm or less, and still more preferably 20 nm or less. The lower limit is, for example, 0.5 nm or more.

The average primary particle diameter of the particles is a value obtained by measuring diameters of any 100 particles by observation with a transmission electron microscope, and arithmetically averaging the diameters of the 100 particles. In a case where the metal oxide particles are not perfectly circular, a major axis is the diameter.

A content of the particles in the transfer layer B layer is not particularly limited, but is preferably 1% to 95% by mass and more preferably 20% to 90% by mass with respect to the total mass of the transfer layer B layer.

The metal oxide particles may be used alone or in combination of two or more thereof.

A refractive index of the transfer layer B layer is preferably 1.55 or more, more preferably 1.60 or more, and still more preferably 1.65 or more. The upper limit is not particularly limited, but is preferably 1.90 or less, more preferably 1.85, and still more preferably 1.80 or less.

A thickness of the transfer layer B layer is preferably 0.3 μm or less, more preferably 0.02 to 0.2 μm, still more preferably 0.04 to 0.2 μm, and particularly preferably 0.05 to 0.1 μm.

The transfer layer (the transfer layer A layer and/or the transfer layer B layer) can be formed by applying a solution in which the above-described various components are dissolved in a solvent to a temporary support and drying the solution.

In addition, the transfer layer B layer (or the transfer layer A layer) may be formed by applying a solution in which the above-described various components are dissolved in a solvent to the transfer layer A layer (or the transfer layer B layer) which has been pre-formed and drying the solution.

A thickness of the transfer layer as a whole is not particularly limited, but is preferably 0.1 to 100 μm, more preferably 1 to 50 μm, and still more preferably 3 to 20 μm.

Protective Film

The transfer film preferably has a protective film that is in contact with a surface which does not face the temporary support.

As the protective film, a resin film having heat resistance and solvent resistance can be used, and examples thereof include polyolefin films such as a polyethylene terephthalate film, a polypropylene film, and a polyethylene film. In addition, as the protective film, a resin film formed of the same material as in the above-described support film may be used.

Among these, a polyolefin film is preferable, a polypropylene film or a polyethylene film is more preferable, and a polyethylene film is still more preferable.

A thickness of the protective film is preferably 1 to 100 μm, more preferably 5 to 50 μm, still more preferably 5 to 40 μm, and particularly preferably 15 to 30 μm. From the viewpoint that a mechanical strength is excellent, the thickness of the protective film is preferably 1 μm or more, and from the viewpoint of cost, the thickness of the protective film is preferably 100 μm or less.

In order to make it easier to peel off the protective film from the transfer layer, it is preferable that an adhesive force between the protective film and the transfer layer is smaller than an adhesive force between the temporary support and the transfer layer.

In addition, the protective film preferably has 5 pieces/m² or less of the number of fisheyes with a diameter of 80 μm or more in the protective film. The “fisheye” means that, in a case where a material is hot-melted, kneaded, extruded, biaxially stretched, cast or the like to manufacture a film, foreign substances, undissolved substances, oxidatively deteriorated substances, and the like of the material are incorporated into the film.

The number of particles having a diameter of 3 μm or more included in the protective film is preferably 30 particles/mm² or less, more preferably 10 particles/mm² or less, and still more preferably 5 particles/mm² or less. As a result, it is possible to suppress defects caused by ruggedness due to the particles included in the protective film being transferred to the transfer layer.

In the protective film, from the viewpoint of imparting take-up property, an arithmetic average roughness Ra on a surface opposite to a surface in contact with the transfer layer is preferably 0.01 μm or more, more preferably 0.02 μm or more, and still more preferably 0.03 μm or more. On the other hand, the upper limit value is preferably less than 0.50 μm, more preferably 0.40 μm or less, and still more preferably 0.30 μm or less.

In the protective film, from the viewpoint of defect suppression during transfer, an arithmetic average roughness Ra on a surface in contact with the transfer layer is preferably 0.01 μm or more, more preferably 0.02 μm or more, and still more preferably 0.03 μm or more. On the other hand, the upper limit value is preferably less than 0.50 μm, more preferably 0.40 μm or less, and still more preferably 0.30 μm or less.

The transfer film may further have at least one layer selected from the group consisting of an adhesive layer and a gas barrier layer on the surface of the protective film.

(Manufacturing Method of Sensor Film Using Transfer Film)

Using the above-described transfer film, for example, a manufacturing method of the sensor film including the following steps A to D can be performed.

Step A: step of forming the above-described sensor electrode and the above-described lead wire on the substrate

Step B: step (transfer step) of transferring, to the substrate, a transfer layer (photosensitive resin layer) using a transfer film having, on a temporary support, a transfer layer (photosensitive resin layer) which becomes the first protective layer and the second protective layer after transfer to form a photosensitive resin layer

Step C: step (exposing step) of exposing (exposing in a patterned manner) a portion of the transfer layer where the second protective layer is formed

Step D: step (developing step) of developing the transfer layer to form a portion (exposed portion) exposed in the transfer layer as the second protective layer and to partially remove a portion (non-exposed portion) not exposed in the transfer layer as the first protective layer

According to such a method, the first protective layer and the second protective layer can be formed step by step without forming them individually, which is labor-saving.

Step A

The step A can be performed by a known method.

Examples thereof include a method in which a precursor layer of the sensor electrode and a precursor layer of the lead wire are formed on the substrate by a sputtering method or the like, and these precursor layers are patterned into a desired form by a chemical etching method or the like to form the sensor electrode and the lead wire. The sensor electrode and the lead wire may be patterned so as to be in contact with each other and a contact point thereof may be conducted, or after patterning, a connection electrode may be further formed on the sensor electrode to make the sensor electrode and the lead wire conductive.

Step B (Transfer Step)

The step B is step (transfer step) of transferring, to the substrate, a transfer layer using a transfer film having, on a temporary support, a transfer layer (photosensitive resin layer) which becomes the first protective layer and the second protective layer after transfer to form a photosensitive resin layer.

In the transfer step, the transfer film and the substrate are bonded together to manufacture a laminate. In this case, the surface of the transfer film opposite to the temporary support (that is, the transfer layer) comes into contact with the substrate.

In a case where the protective film is provided on the transfer layer of the transfer film (the surface of the transfer layer opposite to the temporary support), the protective film is removed and then the transfer layer is transferred to the substrate.

The transfer film is as described above.

In the step B (transfer step), it is preferable to press the transfer layer side of the transfer film onto the substrate while heating the transfer layer and/or the substrate.

A heating temperature and a pressing pressure in this case are not particularly limited, but the heating temperature is preferably 70° C. to 130° C. and the pressing pressure is preferably approximately 0.1 to 1.0 MPa (approximately 1 to 10 kgf/cm²).

In a case of performing pressing using a roller (rubber roller or the like), a roller temperature is preferably 70° C. to 130° C., and a pressing pressure is preferably approximately 0.5 to 5.0 N/cm.

From the viewpoint that adhesiveness and followability are more excellent, the pressing is preferably performed under reduced pressure.

In addition, instead of the heating treatment of the transfer layer and/or the substrate in the transfer step, the substrate may be subjected to a preheating treatment before the transfer step in order to further improve the adhesiveness.

Step C (Exposing Step)

In the exposing step, after the above-described transfer step, a portion of the transfer layer where the second protective layer should be formed is exposed (exposed in a patterned manner).

In the exposing step, a part of the transfer layer is exposed by imagewise irradiating with actinic ray through a mask pattern.

The transfer layer is cured in a region (exposed portion) irradiated with the actinic ray. The cured portion of the transfer layer becomes the second protective layer through the step D (developing step). On the other hand, the transfer layer does not cure in a region (non-exposed portion) not irradiated with the actinic ray.

Examples of a light source of the actinic ray in the exposing step include a known light source.

As the light source, a light source which effectively irradiates the transfer layer with light having a wavelength which can be exposed (for example, 365 nm or 405 nm) is preferable, and examples thereof include a carbon arc lamp, a mercury vapor arc lamp, an ultra-high pressure mercury lamp, a high pressure mercury lamp, and a xenon lamp.

In addition, as the light source, an Ar ion laser or a semiconductor laser may be used, or a photographic flood bulb or a solar lamp may be used.

Further, a method of imagewise irradiating with actinic ray without using a mask pattern, such as a direct drawing method using a laser exposure method, may be adopted.

An exposure amount in the exposing step varies depending on the device used and the composition of the transfer layer, but is preferably 5 to 1000 mJ/cm² and more preferably 10 to 700 mJ/cm². From the viewpoint of excellent photocuring properties, 5 mJ/cm² or more is preferable, and from the viewpoint of resolution, 1000 mJ/cm² or less is preferable.

An exposure atmosphere in the exposing step is not particularly limited, and the exposure can be performed in air, nitrogen, or vacuum.

Step Ca (Placing Step)

It is also preferable to perform a placing step between the step B and the step C and/or between the step C and the step D.

The placing step is a step of allowing the transfer layer to stand (placing the transfer layer) after the step B and/or after the step C, before performing the next step.

By performing such a step, a development resistance of the non-exposed portion in the transfer layer is removed, and in a case of performing the step D, the transfer layer in the non-exposed portion is not completely removed and it is easy to leave the non-exposed portion as the first protective layer.

A placing time may be appropriately adjusted so that the first protective layer can have a desired thickness, and is preferably 12 to 96 hours, for example.

The placing may be performed at room temperature (for example, 20° C. to 28° C.), and may be performed at a lower temperature or a higher temperature.

A humidity during placing may be, for example, 10 to 80% RH.

Step Cb (Peeling Step)

It is also preferable to perform a peeling step between the step B and the step C or between the step C and the step D.

The peeling step is a step of peeling off the temporary support in the transfer film from the laminate in which the transfer film and the substrate are bonded together.

Step D (Developing Step)

The step D is a step of developing the transfer layer to form a portion (exposed portion) exposed in the transfer layer as the second protective layer and to partially remove a portion (non-exposed portion) not exposed in the transfer layer as the first protective layer.

Specifically, by bringing a developer into contact with the transfer layer exposed by peeling off the temporary support, the portion (non-exposed portion) not cured in the transfer layer is partially removed. As a result, the non-exposed portion of the transfer layer is mainly removed from a vicinity of the surface, and the transfer layer which has not been completely removed forms the first protective layer in the non-exposed portion.

The exposed portion of the transfer layer is not removed by the developer, and the second protective layer is formed on the exposed portion.

Examples of the developer include an alkaline aqueous solution, an aqueous developer, and an organic solvent-based developer. The development treatment in the developing step is performed by a known method such as spraying, reciprocal dipping, brushing, and scraping using these developers.

As the developer, an alkaline aqueous solution is preferable because it is safe and stable and has good operability. As the alkaline aqueous solution, 0.1% to 5% by mass sodium carbonate aqueous solution, 0.1% to 5% by mass potassium carbonate aqueous solution, 0.1% to 5% by mass sodium hydroxide aqueous solution, or 0.1% to 5% by mass sodium tetraborate aqueous solution is preferable.

A pH of the alkaline aqueous solution used as the developer is preferably in a range of 9 to 11. A temperature of the developer is adjusted according to developability of the transfer layer. In addition, the alkaline aqueous solution may include a surfactant, an anti-foaming agent, a small amount of an organic solvent for accelerating the development, or the like.

In addition, as the developer, an aqueous developer of water or an alkali aqueous solution and one or more kinds of organic solvents may be used. Here, examples of a base included in the alkali aqueous solution include sodium carbonate, potassium carbonate, sodium hydroxide, and sodium tetraborate described above, and also include borax, sodium metasilicate, tetramethylammonium hydroxide, ethanolamine, ethylenediamine, diethylenetriamine, 2-amino-2-hydroxymethyl-1,3-propanediol, 1,3-diaminopropanol-2, and morpholine.

Examples of the organic solvent include methyl ethyl ketone, acetone, ethyl acetate, alkoxyethanol having an alkoxy group having 1 to 4 carbon atoms, ethyl alcohol, isopropyl alcohol, butyl alcohol, diethylene glycol monomethyl ether, diethylene glycol monoethyl ether, and diethylene glycol monobutyl ether. These compounds are used alone or in combination of two or more kinds thereof.

A content of the organic solvent in the aqueous developer is preferably 2% to 90% by mass with respect to the total mass of the aqueous developer. A pH of the aqueous developer is not particularly limited as long as the transfer layer can be developed, but is preferably 8 to 12 and more preferably 9 to 10.

In addition, the aqueous developer may contain a small amount of additives such as a surfactant and an anti-foaming agent.

Examples of the organic solvent-based developer include 1,1,1-trichloroethane, N-methylpyrrolidone, N, N-dimethylformamide, cyclohexanone, methyl isobutyl ketone, and γ-butyrolactone. In order to prevent ignition, the organic solvent-based developer preferably contains water in a range of 1% to 20% by mass.

Two or more kinds of the above-described developers may be used in combination as necessary.

An operating temperature of the developer may be appropriately adjusted in consideration of the thickness of the first protective layer, and the like, and is, for example, 15° C. to 60° C.

A time of the development treatment may be appropriately adjusted in consideration of the thickness of the first protective layer, and the like, and is, for example, 20 to 300 seconds.

After the development treatment, a rinsing step may be performed to remove excess developer. The rinsing step is, for example, a treatment of washing the currently treated laminate with water and/or an organic solvent or the like.

It is also preferable to heat the laminate after the development treatment at 60° C. to 250° C. and/or expose the laminate to an exposure amount of 200 to 10000 mJ/cm². By performing such a treatment, the first protective layer can be cured to be a strong layer, or the second protective layer can be more completely cured.

<Application>

The sensor film according to the embodiment of the present invention can be applied to various applications. Examples thereof include a touch sensor (preferably, a capacitive touch sensor) and an electromagnetic wave shield. In particular, the sensor film according to the embodiment of the present invention can be suitably applied to a touch sensor including the sensor film and a flexible wiring board connected to the connection terminal in the sensor film, and more suitably applied to a capacitive touch sensor.

The present invention also relates to an image display device including the sensor film.

The above-described image display device includes an image display element such as a liquid crystal display device and an organic electroluminescence display element and the sensor film used as the touch sensor described above.

### EXAMPLES

Hereinafter, the present invention will be described in detail with reference to Examples. The material, the amount used, the ratio, the process contents, the process procedure, and the like shown in the following examples can be appropriately changed, within a range not departing from the gist of the present disclosure. Therefore, the scope of the present invention is not limited to the specific examples described below. “part” and “%” are based on mass unless otherwise specified.

In the following examples, a weight-average molecular weight of a resin is a weight-average molecular weight obtained by performing polystyrene conversion of a value measured by gel permeation chromatography (GPC).

A polymer compositional ratio is a mol ratio unless otherwise specified.

### Examples 1 to 4 and Comparative Examples 1 and 2

[Production of Test Piece]

<Preparation of Coating Liquid for Forming Photosensitive Resin Layer>

Materials A-1 to A-li, which are coating liquids for forming a photosensitive resin layer, were prepared so as to have compositions shown in Table 1 below.

A numerical value described together with each constitutional unit in a binder polymer P-1 is a content ratio (molar ratio) of the constitutional unit.

TABLE 1

| | | Material | Material | Material | Material | Material | Material | Material | Material | Material | Material | Material |
|---|---|---|---|---|---|---|---|---|---|---|---|---|
| | Raw material | A-1 | A-2 | A-3 | A-4 | A-5 | A-6 | A-7 | A-8 | A-9 | A-10 | A-11 |
| Polymerizable | Tricyclodecane dimethanol diacrylate (A-DCP, manufactured by Shin-Nakamura | 5.60 | 5.60 | 0.45 | 2.28 | 2.46 | 2.05 | — | — | — | 2.28 | 2.28 |
| compound | Chemical Co., Ltd.) | | | | | | | | | | | |
| | Monomer having carboxy group ARONIX TO-2349 (manufactured by Toagosei Co., Ltd.) | 0.93 | 0.93 | 0.74 | 0.76 | 1.03 | 0.85 | 0.88 | 0.94 | 0.76 | 0.76 | 0.76 |
| | Urethane acrylate 8UX-015A (manufactured by Taisei Fine Chemical Co., Ltd.) | 2.80 | 2.80 | — | — | — | — | — | — | — | — | — |
| | A-NOD-N (manufactured by Shin-Nakamura Chemical Co., Ltd.) | | | 0.68 | 0.70 | 0.75 | 0.62 | 2.45 | 3.34 | — | 0.70 | 0.70 |
| | A-DPH (manufactured by Shin-Nakamura Chemical Co., Ltd.) | | | 2.00 | 4.32 | 4.66 | 3.87 | 2.29 | 3.07 | 4.32 | 4.32 | 4.32 |
| | KAYARAD R-604 (manufactured by Nippon Kayaku Co., Ltd.) | | | — | — | — | — | 2.44 | 3.34 | — | — | — |
| Binder | P-1 (acid value: 95 mgKOH/g, Mw: 29000, Mn: 13700) | 15.44 | 15.44 | — | — | — | — | — | 17.91 | — | — | — |
| polymer | P-2 solution (solid content: 36.5 wt %, acid value: 95 mgKOH/g, Mw: 17000, Mn: 6200) | | | 36.28 | — | — | — | — | — | — | — | — |
| | P-3 solution (solid content: 36.2 wt %, acid value: 124 mgKOH/g, Mw: 18000, Mn: 7800) | | | — | 33.77 | 32 | 36.17 | 34.17 | — | — | 33.77 | 33.77 |
| | P-4 solution (solid content: 36.2 wt %, acid value: 124 mgKOH/g, Mw: 18000, Mn: 7800) | | | — | — | — | — | — | — | 33.77 | — | — |
| Photopoly- | 1-[9-ethyl-6-(2-methylbenzoyl)-9H-carbazol-3-yl]ethanone-1-(O-acetyloxime) (Irgacure | 0.11 | | | | | | | | | | |
| merization | OXE02, manufactured by BASF SE) | | | | | | | | | | | |
| initiator | l-[4-(phenylthio)phenyl]-1,2-octanedione-2-(O-benzoyloxime) (Irgacure OXE01, | | 0.11 | | | | | | | | | |
| | manufactured by BASF SE) | | | | | | | | | | | |
| | 2-methyl-1-(4-methylthiophenyl)-2-morpholinopropan-1-one (Irgacure 907, | 0.21 | 0.21 | | | | | | | | | |
| | manufactured by BASF SE) | | | | | | | | | | | |
| | 1-(biphenyl-4-yl)-2-methyl-2-morpholinopropan-1-one (APi-307, manufactured by | | | | 0.19 | 0.20 | 0.17 | 0.44 | 0.27 | — | 0.19 | 0.19 |
| | Shenzhen UV-ChemTech Co., Ltd.) | | | | | | | | | | | |
| | Irgacure OXE03, manufactured by BASF SE | | | — | — | — | — | — | — | 0.09 | — | — |
| | 2-(dimethylamino)-2-[(4-methylphenyl)methyl]-1-[4-(4-morpholinyl)phenyl]-1-butanone | | | — | — | — | — | 0.16 | 0.09 | — | — | — |
| | (Irgacure 379EG, manufactured by BASF SE) | | | | | | | | | | | |
| | 2-hydroxy-4′-(2-hydroxyethoxy)-2-methyl propiophenone (Irgacure 2959, manufactured | | | — | — | — | — | — | — | 0.40 | — | — |
| | by BASF SE) | | | | | | | | | | | |
| | N-phenylglycine (manufactured by TOKYO CHEMICAL INDUSTRY CO., LTD.) | 0.03 | | 0.03 | 0.03 | 0.03 | 0.03 | | | 0.03 | 0.03 | 0.03 |
| Blocked | WT32-B75P (manufactured by Asahi Kasei Corporation) | 3.62 | | | | | | | | | | |
| isocyanate | TPA-B80E (manufactured by Asahi Kasei Corporation) | | 3.62 | | | | | | | | | |
| compound | Karenz AOI-BM (manufactured by SHOWA DENKO K.K.) | | | — | — | — | — | — | — | 4.46 | — | — |
| | X6010-4 (manufactured by Asahi Kasei Corporation) | | | — | 4.46 | 4.46 | 4.46 | — | — | — | 4.46 | 4.46 |
| | DURANATE SBN-70D (manufactured by Asahi Kasei Corporation) | | | — | — | — | — | 0.79 | — | — | — | — |
| | Compound B shown below | | | — | 0.74 | 074 | 0.74 | — | — | — | — | 0.74 |
| | Compound C shown below | | | — | — | — | — | — | — | — | 0.74 | — |
| Additive | 1,2,4-triazole (manufactured by Otsuka Chemical Co.,Ltd.) | | | — | — | — | — | — | — | — | 0.09 | — |
| | benzimidazole (manufactured by TOKYO CHEMICAL INDUSTRY CO., LTD.) | 0.10 | | 0.03 | 0.03 | 0.03 | 0.03 | 0.07 | 0.09 | — | — | 0.03 |
| | 5-amino-1H-tetrazole (manufactured by TOKYO CHEMICAL INDUSTRY CO., LTD.) | | 0.05 | — | — | — | — | — | — | 0.09 | — | — |
| | isonicotinamide (manufactured by TOKYO CHEMICAL INDUSTRY CO., LTD.) | | | 0.13 | 0.01 | 0.01 | 0.01 | 0.22 | — | — | — | 0.01 |
| | SMA EF-40 (manufactured by TOMOEGAWA CO., LTD.) | | | 0.30 | 0.30 | 0.30 | 0.30 | — | — | 0.30 | 0.30 | 0.30 |
| | MEGAFACE F551A (manufactured by DIC Corporation) | 0.16 | | 0.16 | 0.16 | 0.16 | 0.16 | — | — | 0.16 | 0.16 | — |
| | MEGAFACE EXP MFS-578 (manufactured by DIC Corporation) | | | — | — | — | — | 0.24 | 0.24 | — | — | 0.16 |
| | octamethylcyclotetrasioxane | | 0.16 | | | | | | | | | |
| Solvent | 1-methoxy-2-propylacetate | 31.00 | 31.08 | 16.60 | 9.65 | 10.57 | 7.94 | 10.85 | 32.21 | 13.02 | 9.60 | 9.65 |
| | methyl ethyl ketone | 40.00 | 40.00 | 42.60 | 42.60 | 42.60 | 42.60 | 45.00 | 38.50 | 42.60 | 42.60 | 42.60 |

| | | | | | | | | | | | |
|---|---|---|---|---|---|---|---|---|---|---|---|
| Total (part by mass) | 100 | 100 | 100 | 100 | 100 | 100 | 100 | 100 | 100 | 100 | 100 |

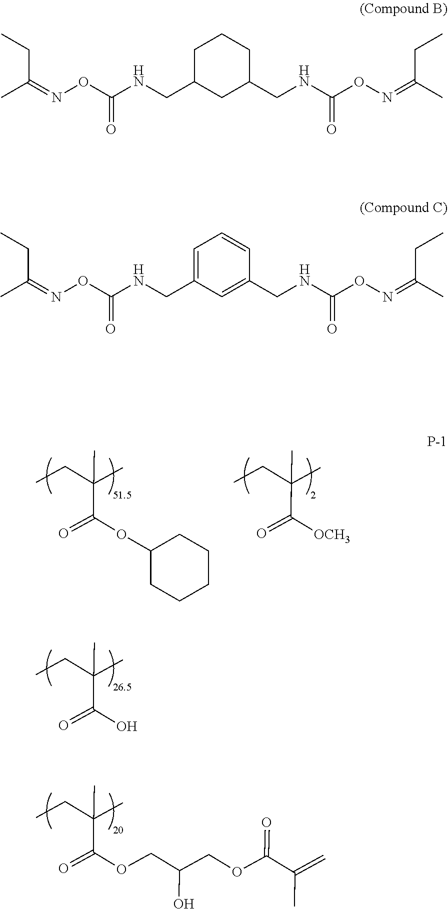

(Preparation of Solution of Binder Polymer P-2 Having Solid Content of 36.3% by Mass)

82.4 g of propylene glycol monomethyl ether was charged into a flask and heated to 90° C. under a nitrogen stream. To this liquid, a solution in which 38.4 g of styrene, 30.1 g of dicyclopentanyl methacrylate, and 34.0 g of methacrylic acid had been dissolved in 20 g of propylene glycol monomethyl ether and a solution in which 5.4 g of a polymerization initiator V-601 (manufactured by FUJIFILM Wako Pure Chemical Corporation) had been dissolved in 43.6 g of propylene glycol monomethyl ether acetate was simultaneously added dropwise over 3 hours. After the dropwise addition, 0.75 g of V-601 was added three times every hour. Thereafter, the reaction was continued for another 3 hours. Thereafter, the reaction solution was diluted with 58.4 g of propylene glycol monomethyl ether acetate and 11.7 g of propylene glycol monomethyl ether. The reaction solution was heated to 100° C. under an air stream, and 0.53 g of tetraethylammonium bromide and 0.26 g of p-methoxyphenol were added thereto. 25.5 g of glycidyl methacrylate (Blemmer GH manufactured by NOF Corporation) was added dropwise thereto over 20 minutes. The reaction was continued at 100° C. for 7 hours to obtain a solution of a binder polymer P-2. The concentration of solid contents of the obtained solution was 36.5%. The weight-average molecular weight in terms of standard polystyrene in GPC was 17000, the dispersity was 2.4, and the acid value of the polymer was 94.5 mgKOH/g. The amount of residual monomer measured by gas chromatography was less than 0.1% by mass with respect to the solid content of the polymer in any of the monomers.

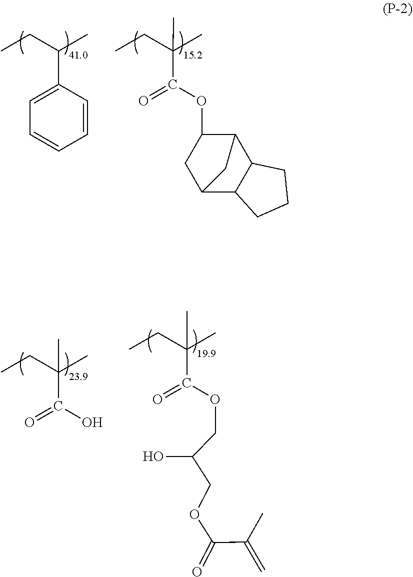

(Preparation of Solution of Binder Polymer P-3 Having Solid Content of 36.2% by Mass)

113.5 g of propylene glycol monomethyl ether was charged into a flask and heated to 90° C. under a nitrogen stream. To this liquid, a solution in which 172 g of styrene, 4.7 g of methyl methacrylate, and 112.1 g of methacrylic acid had been dissolved in 30 g of propylene glycol monomethyl ether and a solution in which 27.6 g of a polymerization initiator V-601 (manufactured by FUJIFILM Wako Pure Chemical Corporation) had been dissolved in 57.7 g of propylene glycol monomethyl ether was simultaneously added dropwise over 3 hours. After the dropwise addition, 2.5 g of V-601 was added three times every hour. Thereafter, the reaction was continued for another 3 hours. Thereafter, the reaction solution was diluted with 160.7 g of propylene glycol monomethyl ether acetate and 233.3 g of propylene glycol monomethyl ether. The reaction solution was heated to 100° C. under an air stream, and 1.8 g of tetraethylammonium bromide and 0.86 g of p-methoxyphenol were added thereto. 71.9 g of glycidyl methacrylate (Blemmer G manufactured by NOF Corporation) was added dropwise thereto over 20 minutes. The reaction was continued at 100° C. for 7 hours to obtain a solution of a binder polymer P-3. The concentration of solid contents of the obtained solution was 36.2%. The weight-average molecular weight in terms of standard polystyrene in GPC was 18000, the dispersity was 2.3, and the acid value of the polymer was 124 mgKOH/g. The amount of residual monomer measured by gas chromatography was less than 0.1% by mass with respect to the solid content of the polymer in any of the monomers.

P-3 (hereinafter, the molar ratio of the repeating units in the formula was 55.1:26.5:1.6:16.9 in the order from the repeating unit on the left side)

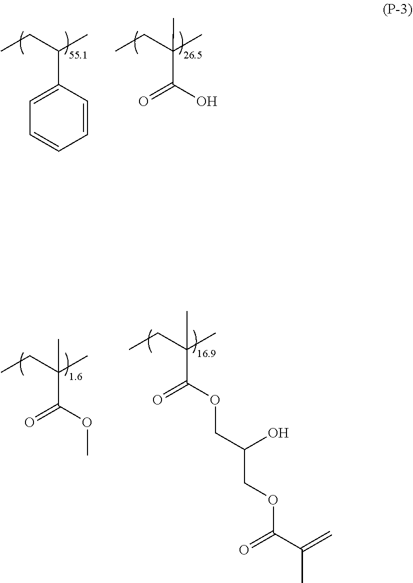

A solution having a solid content of 36.2% by mass solution (solvent: propylene glycol monomethyl ether acetate) of binder polymer P-4 was prepared by changing the type and the amount of the monomer in the synthesis of binder polymer P-3. The obtained binder polymer P-4 had a weight-average molecular weight of 18000, a dispersity of 2.3, and an acid value of 114 mgKOH/g.

P-4 (hereinafter, the molar ratio of the repeating units in the formula was 55.1:24.6:1.6:17.0:1.7 in the order from the repeating unit on the left side)

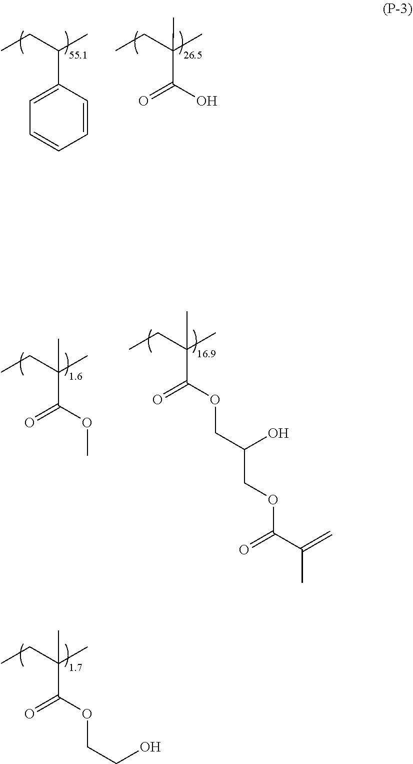

<Manufacturing of Transfer Film>

The material A-1 or A-11, which is the coating liquid for forming a photosensitive resin layer, was applied to a temporary support of a polyethylene terephthalate film having a thickness of 16 μm (LUMIRROR 16KS40 (manufactured by Toray Industries, Inc.)) using a slit-shaped nozzle, in which a coating amount was adjusted so that a film thickness after drying is the thickness of the second protective layer shown in Table 3.

After volatilizing the solvent in the applied materials A-1 to A-11 in a drying zone at 100° C., a protective film (LUMIRROR 16KS40 (manufactured by Toray Industries, Inc.)) was pressed onto the photosensitive resin layer obtained on the above-described film, thereby manufacturing transfer films used in Examples 1 to 18 and Comparative Examples 1 to 3 described later.

<Manufacturing of Transparent Electrode Pattern Film Used for Manufacturing Laminate>

(Formation of Transparent Film)

A cycloolefin resin film having a film thickness of 38 μm and a refractive index of 1.53 was subjected to a corona discharge treatment for 3 seconds under the conditions of an electrode length of 240 mm, a distance between work electrodes of 1.5 mm at an output voltage of 100% and an output of 250 W with a wire electrode having a diameter of 1.2 mm by using a high frequency oscillator, to perform the surface reforming. The obtained film was used as a transparent film substrate.

Next, a material of a material-C shown in the table below was applied onto a transparent film substrate using a slit-shaped nozzle, then irradiated with ultraviolet rays (integrated light amount of 300 mJ/cm²), and dried at approximately 110° C. to manufacture a transparent film having a refractive index of 1.60 and a film thickness of 80 nm on the transparent film substrate.

TABLE 2

| Raw material | Material-C |
|---|---|
| ZrO₂: ZR-010 manufactured by SOLAR CO., LTD. | 2.08 |
| DPHA solution (dipentaerythritol hexaacrylate: 38%, dipentaerythritol pentaacrylate: 38%, | 0.29 |
| 1-methoxy-2-propylacetate: 24%) | |
| Urethane-based monomer; UK OLIGO UA-32P manufactured by SHIN-NAKAMURA | 0.14 |
| CHEMICAL CO., LTD.: non-volatile content: 75%, 1-methoxy-2-propylacetate: 25% | |
| Monomer mixture (polymerizable compound (b2-1) described in paragraph [0111] of | 0.36 |
| JP2012-78528A, n = 1, content of tripentaerythritol octaacrylate: 85%, total of n = 2 and n = 3 as | |
| impurities: 15%) | |
| Polymer solution 1 (structural formula P-25 described in paragraph [0058] of JP2008-146018A, | 1.89 |
| weight-average molecular weight = 35,000, solid content: 45%, 1-methoxy-2-propylacetate: 15%, | |
| 1-methoxy-2-propanol: 40%) | |
| Photoradical polymerization initiator: 2-benzyl-2-dimethylamino-1-(4-morpholinophenyl)butanone | 0.03 |
| (Irgacure (registered trademark) 379, manufactured by BASF SE) | |
| Photopolymerization initiator: Kayacure DETX-S (Nippon Kayaku Co., Ltd., alkylthioxanthone) | 0.03 |
| Polymer solution 2 (polymer having structural formula represented by Formula (3); solution of | 0.01 |
| weight-average molecular weight of 15000, non-volatile content: 30% by mass, methyl ethyl | |
| ketone: 70% by mass) | |
| 1-Methoxy-2-propylacetate | 38.73 |
| Methyl ethyl ketone | 56.80 |
| Total (part by mass) | 100 |

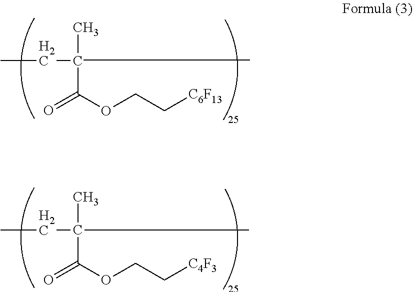

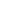

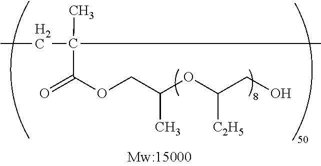

(Formation of Transparent Electrode Pattern)

An ITO thin film having a thickness of 30 nm and a refractive index of 1.82 was formed on the transparent film substrate on which the transparent film obtained above had been laminated by a known sputtering method, and a copper thin film having a thickness of 200 nm was formed on the ITO thin film.

Thereafter, the ITO thin film and the copper thin film were respectively patterned by a known chemical etching method to form an ITO transparent electrode pattern (sensor electrode) and a copper lead wire, thereby obtaining a transparent film substrate having a transparent electrode pattern. A terminal of the copper lead wire on an opposite side of the transparent electrode pattern (sensor electrode) was a connecting part (connection terminal) with an external circuit.

<Manufacturing of Transparent Laminate>

(Manufacturing of Transparent Laminate of Example 1)

The protective film of the transfer film of each Example and Comparative Example was peeled off, and the peeled side was laminated on the transparent film substrate on a side where the ITO transparent electrode pattern and the copper lead wire were formed to obtain a transparent film substrate on which the transfer film was laminated.

In this case, the film was laminated so as to cover the transparent film, the transparent electrode pattern, and the copper lead wire. The lamination was performed under the conditions in which a temperature of transparent film substrate was 40° C., a rubber roller temperature was 100° C., a linear pressure was 3 N/cm, and a transportation speed was 2 m/min, by using a vacuum laminator manufactured by MCK Co., Ltd.

Thereafter, using a proximity type exposure machine (manufactured by Hitachi High-Tech Electronics Engineering Co., Ltd.) including an ultra-high pressure mercury lamp, a surface of an exposure mask and the temporary support were closely attached, and the transparent film substrate was exposed in a patterned shape with an exposure amount of 120 mJ/cm² (i ray) through the temporary support. The exposure mask was a quartz exposure mask having a pattern for forming an overcoat, and the connecting part with the external circuit was shielded from light.

That is, in the pattern exposure, the entire surface of the lead wire other than the connecting part (connection terminal) with the external circuit was exposed, and only the connecting part (connection terminal) was not irradiated with light.

After the pattern exposure, the transparent film substrate was allowed to stand for 48 hours in an atmosphere of 25° C. and 50% RH.

After peeling off the temporary support from the transparent film substrate, development treatment was performed at 32° C. in a 1% aqueous solution of sodium carbonate for 60 seconds. Thereafter, an ultrapure water was sprayed onto the developed transparent film substrate from an ultrahigh pressure washing nozzle. Subsequently, air was blown to remove water on the transparent film substrate, and the transparent film substrate was exposed (post-exposed) with an exposure amount of 400 mJ/cm² (i-rays) using a post-exposure machine (manufactured by Ushio, Inc.) having a high pressure mercury lamp. Thereafter, a post-baking treatment at 145° C. for 30 minutes was performed to form a transparent laminate (sensor film) including, on the transparent film substrate, the transparent film, the transparent electrode pattern, the copper lead wire, and a cured film (first protective layer and second protective layer) of the coating liquid for forming a photosensitive resin layer in this order.

As a result, the second protective layer having a thickness of 8 μm was formed on the exposed portion (portion other than the connecting part (connection terminal) with the external circuit in the lead wire), and the first protective layer having a thickness of 0.020 μm was formed on the non-exposed portion (connecting part (connection terminal) with the external circuit in the lead wire).

(Manufacturing of Transparent Laminates of Examples 2 to 18 and Comparative Examples 1 to 3)

The thickness of the first protective layer could be changed by changing a time (placing time) from the pattern exposure to the development treatment, and as the time was longer, the thickness of the first protective layer was thicker. Transparent laminates (sensor films) of Examples 2 to 18 and Comparative Examples 1 to 3 were manufactured in the same manner as in Example 1, except that the thickness of the first protective layer was adjusted to be the thickness shown in Table 3 by changing the protective layer material (type of coating liquid for forming a photosensitive resin layer) and/or the placing time.

[Evaluation of Transparent Laminate]

<Dielectric Breakdown Voltage>

Instead of the above-described transparent electrode pattern film, a transfer film same as that used in each Example and Comparative Example was transferred onto a copper plate having a thickness of 500 μm to obtain a laminated copper plate. The laminated copper plate was exposed to the entire surface with an exposure amount of 120 mJ/cm² (i-rays) through the temporary support, and the temporary support was peeled off.

Further, the laminated copper plate was exposed to the entire surface with an exposure amount of 400 mJ/cm² (i-rays) using a post-exposure machine (manufactured by Ushio, Inc.) having a high pressure mercury lamp. Thereafter, the laminated copper plate was post-baked at 145° C. for 30 minutes, thereby obtaining a sample for measuring material dielectric breakdown voltage, which had, on a copper plate, a resin layer formed of substantially the same material as the above-described first protective layer and second protective layer.

This sample was allowed to stand for 24 hours in an atmosphere of 25° C. and 50% RH, and then the following measurement was carried out in an atmosphere of 25° C. and 50% RH.

The produced sample for measuring the dielectric breakdown voltage was tested using Hipot Tester TOS5101 (manufactured by KIKUSUI ELECTRONICS CORPORATION) to measure a dielectric breakdown voltage of the resin layer. A test voltage range was set to 5 kV, an upper limit reference value was set to 10 mA, and a test time was set to 1 second. The results are shown in Table 4.

<Evaluation of Copper Discoloration by Wet Heat Test>

After allowing the transparent laminate of each Example and Comparative Example to stand in a wet heat environment of 85° C. and 85% RH for 50 hours, a color of copper at the connecting part (connection terminal) with the external circuit was observed, and a change in color of copper was classified into the following A to C.

A or B is a practical level, and A is preferable.

A: there was no change in color of copper before and after the wet heat test.

B: copper was reddish after the wet heat test.

C: copper had turned blue after the wet heat test.

<Evaluation of Drivability>

Using the transparent laminate of each Example and Comparative Example, an electrostatic capacity-type touch panel member (input device) was manufactured by a known method.

The manufactured touch panel member was attached to a liquid crystal display element manufactured by a method described in paragraphs 0097 to 0119 of JP2009-047936A, thereby manufacturing a liquid crystal display device with a touch panel, including the touch panel member as an input device and a liquid crystal display device as a display device. The manufactured liquid crystal display device with a touch panel was allowed to stand for 50 hours in a wet heat environment at 85° C. and 85% RH.

A drivability of the manufactured liquid crystal display device with a touch panel was evaluated by classifying it into the following A to C.

In a case of being evaluated as A, it can be judged that an electrical connectivity at the connecting part (connection terminal) with the external circuit is good.

A: could be driven normally

B: driven but may malfunction

C: driven but malfunctions more often than B

D: not driven

The table below shows the test results.

In the table, the column of “Dielectric breakdown voltage” shows the dielectric breakdown voltage of the resin layer produced by using the coating liquid for forming a photosensitive resin layer used in each Example. The resin layer and the first protective layer described above were formed of substantially the same material, and the dielectric breakdown voltage (V/μm) was also the same.

In Comparative Example 1, the existence of the first protective layer could not be confirmed on the connecting part (connection terminal) with the external circuit.

TABLE 3

| | Characteristics | | | | | Evaluation | |
|---|---|---|---|---|---|---|---|
| | | | | | Thickness of | Evaluation of | |
| | Coating liquid | Thickness | Thickness | Dielectric | first protective | copper | |
| | for forming | of first | of second | breakdown | film × dielectric | discoloration | Evaluation |
| | photosensitive | protective | protective | voltage | breakdown | by wet heat | of |
| | resin layer | film (μm) | film (μm) | (V/μm) | voltage (V) | test | drivability |
| Example 1 | Material A-1 | 0.02 | 8 | 200 | 4.0 | B | A |
| Example 2 | Material A-1 | 0.001 | 8 | 200 | 0.2 | B | A |
| Example 3 | Material A-2 | 0.02 | 8 | 350 | 7.0 | B | A |
| Example 4 | Material A-2 | 0.05 | 8 | 350 | 17.5 | A | A |
| Example 5 | Material A-2 | 0.035 | 8 | 350 | 12.3 | A | A |
| Example 6 | Material A-2 | 0.06 | 8 | 350 | 21.0 | A | B |
| Example 7 | Material A-2 | 0.08 | 8 | 350 | 28.0 | A | C |
| Example 8 | Material A-2 | 0.035 | 5 | 350 | 12.3 | A | A |
| Example 9 | Material A-3 | 0.02 | 5 | 200 | 4.0 | B | A |
| Example 10 | Material A-4 | 0.02 | 5 | 200 | 4.0 | B | A |
| Example 11 | Material A-4 | 0.02 | 3 | 200 | 4.0 | B | A |
| Example 12 | Material A-5 | 0.02 | 5 | 200 | 4.0 | B | A |
| Example 13 | Material A-6 | 0.02 | 5 | 200 | 4.0 | B | A |
| Example 14 | Material A-7 | 0.02 | 5 | 200 | 4.0 | B | A |
| Example 15 | Material A-8 | 0.02 | 8 | 200 | 4.0 | B | A |
| Example 16 | Material A-9 | 0.02 | 5 | 200 | 4.0 | B | A |
| Example 17 | Material A-10 | 0.02 | 5 | 200 | 4.0 | B | A |
| Example 18 | Material A-11 | 0.02 | 5 | 200 | 4.0 | B | A |
| Comparative | Material A-1 | 0 | 8 | 200 | 0 | C | B |
| Example 1 | | | | | | | |
| Comparative | Material A-2 | 0.12 | 8 | 350 | 42.0 | A | D |
| Example 2 | | | | | | | |
| Comparative | Material A-1 | 0.16 | 8 | 200 | 32.0 | A | D |
| Example 3 | | | | | | | |

As shown in the above table, it was confirmed that the object of the present invention can be accomplished by using the sensor film according to the embodiment of the present invention.

Among these, in a case where the value represented by D×B (D: thickness (μm) of first protective layer, B: dielectric breakdown voltage (V/μm) of first protective layer) was more than 10.0 V and 20.0 V or less, it was confirmed that the effects of the present invention were more excellent (see the results of Example 4).

On the other hand, in a case where the sensor films of Comparative Examples were used, the object of the present invention could not be accomplished.

In Comparative Example 1, it is considered that the connection terminal could not be sufficiently prevented from being corroded because the sensor film did not have the first protective layer.

In Comparative Example 2, it is considered that D×B was too large and the electrical connectivity was adversely affected.

### Examples 19 to 22

In the manufacturing of the transfer film used in Examples 1 to 4, after applying the coating liquid for forming a photosensitive resin layer and volatilizing the solvent in a drying zone at 100° C., a material B-1 having a formulation shown in the table below, which is a coating liquid for forming a transparent resin layer, was applied to the formed photosensitive resin layer using a slit-shaped nozzle with a coating amount such that a film thickness after drying was 70 nm. The coating film of the applied material B-1 was dried at a drying temperature of 80° C. to form a second transparent layer on the photosensitive resin layer. A refractive index of the second transparent layer was 1.68. A protective film (LUMIRROR 16KS40 (manufactured by Toray Industries, Inc.)) was pressed onto the second transparent layer to produce a transfer film.

TABLE 4

| | | Material | Material | Material | Material |
|---|---|---|---|---|---|
| | | B-1 | B-2 | B-3 | B-4 |
| NanoUse OZS-30M: ZrO₂ particles (containing tin oxide) | | 4.88 | 4.34 | 4.34 | 4.34 |
| methanol dispersion liquid (non-volatile content: 30.5%) | | | | | |
| manufactured by Nissan Chemical Corporation | | | | | |
| Ammonia water (25%) | | 7.84 | 7.84 | 7.84 | 7.84 |
| Binder | Copolymer resin of methacrylic acid and allyl | 0.07 | 0.21 | 0.21 | 0.21 |
| polymer | methacrylic acid (Mw: 38,000, composition ratio = | | | | |
| | 20/80) | | | | |
| | ARUFON UC-3920 (manufactured by Toagosei Co., | 0.02 | 0.01 | 0.01 | 0.01 |
| | Ltd.) | | | | |

| | | | | |
|---|---|---|---|---|
| Monomer having carboxy group | 0.03 | 0.03 | 0.03 | 0.03 |
| ARONIX TO-2349 (manufactured by Toagosei Co., Ltd.) | | | | |
| 1,2,4-triazole (manufactured by Otsuka Chemical Co., Ltd.) | 0.03 | | | 0.03 |
| N-methyldiethanolamine (NIPPON NYUKAZAI CO., LTD.) | | 0.03 | 0.03 | 0.03 |
| Adenine (KJ Chemicals Corporation) | | 0.03 | 0.03 | |
| MEGAFACE F444 (manufactured by DIC Corporation) | 0.01 | 0.01 | | |
| FTERGENT 212M (manufactured by NEOS COMPANY | | | 0.04 | 0.04 |
| LIMITED) | | | | |
| Ion exchange water | 20.9 | 21.3 | 21.3 | 21.3 |
| Methanol | 66.2 | 66.2 | 66.2 | 66.2 |
| Total (part by mass) | 100 | 100 | 100 | 100 |

A transparent laminate (sensor film) was produced in the same manner as in Examples 1 to 4, except that the transfer film having such a second transparent layer was used. All first protective layers (entire layer derived from the coating liquid for forming a photosensitive resin layer and the coating liquid for forming a transparent resin layer) in the obtained transparent laminate (sensor film) satisfied the relationship (0 V<D×B≤30.0 V) represented by the expression (1) as a whole. In addition, in each of the transparent laminates, the evaluation result based on the above-described <Evaluation of copper discoloration by wet heat test> was the evaluation B or higher, and the evaluation based on the above-described <Evaluation of drivability> was the evaluation A.

### Examples 23 to 25

In the manufacturing of the transfer film used in Example 9, after applying the coating liquid for forming a photosensitive resin layer and volatilizing the solvent in a drying zone at 100° C., material B-2 to B-4 having a formulation shown in Table 4, which are coating liquids for forming a transparent resin layer, were applied to the formed photosensitive resin layer using a slit-shaped nozzle with a coating amount such that a film thickness after drying was 70 nm. The coating film of the applied materials B-2 to B-4 was dried at a drying temperature of 80° C. to form a second transparent layer on the photosensitive resin layer. A refractive index of the second transparent layer was 1.68. A protective film (LUMIRROR 16KS40 (manufactured by Toray Industries, Inc.)) was pressed onto the second transparent layer to produce a transfer film.

A transparent laminate (sensor film) was produced in the same manner as in Example 9, except that the transfer film having such a second transparent layer was used. All first protective layers (entire layer derived from the coating liquid for forming a photosensitive resin layer and the coating liquid for forming a transparent resin layer) in the obtained transparent laminate (sensor film) satisfied the relationship (0 V<D×B≤30.0 V) represented by the expression (1) as a whole. In addition, in each of the transparent laminates, the evaluation result based on the above-described <Evaluation of copper discoloration by wet heat test> was the evaluation B or higher, and the evaluation based on the above-described <Evaluation of drivability> was the evaluation A.

### EXPLANATION OF REFERENCES

1: temporary support
2: transfer layer
3: protective film
10: transfer film
100: sensor film
102: substrate
104: sensor electrode
106: lead wire
108: first protective layer
110: second protective layer
112: connection terminal

What is claimed is:

1. A sensor film comprising:
a substrate;
a sensor electrode which is disposed on the substrate;
a lead wire which is disposed on the substrate, conducts with the sensor electrode, and has a connection terminal;
a first protective layer with its film thickness of 0.12 μm or less which is disposed on the connection terminal; and
a second protective layer with its film thickness of 1 μm or more which is disposed on at least the sensor electrode or a portion of the lead wire other than the connection terminal,
wherein the first protective layer satisfies a relationship represented by the following expression (1),
0 V<D×B≤30.0 V (1)
D: Thickness (μm) of the first protective layer
B: Dielectric breakdown voltage (V/μm) of the first protective layer.

2. The sensor film according to claim 1,
wherein the lead wire includes one or more metals selected from the group consisting of copper and silver.

3. The sensor film according to claim 1,
wherein the D is 0.001 μm or more.

4. The sensor film according to claim 1,
wherein the B is 400 V/μm or less.

5. The sensor film according to claim 1,
wherein the first protective layer satisfies a relationship represented by the following expression (3),
10.0 V<D×B≤20.0 V. (3)

6. The sensor film according to claim 1,
wherein the first protective layer includes an azole compound.

7. The sensor film according to claim 6,
wherein the azole compound is one or more compounds selected from the group consisting of triazoles, tetrazoles, imidazoles, and thiadiazoles.

8. The sensor film according to claim 1,
wherein the first protective layer includes a binder polymer having a constitutional unit derived from (meth)acrylic acid.

9. The sensor film according to claim 1,
wherein the first protective layer includes a compound having a tricyclodecane skeleton.

10. The sensor film according to claim 1,
wherein the film thickness of the first protective layer is 0.08 μm or less.

11. The sensor film according to claim 1,
wherein the film thickness of the second protective layer is 20 μm or less.

12. A touch sensor comprising:
the sensor film according to claim 1; and
a flexible wiring board connected to the connection terminal.

13. An image display device comprising:
the touch sensor according to claim 12.
